(19) United States
(12) Patent Application Publication
(10) Pub. No.: US 2025/0185462 A1
(43) Pub. Date: Jun. 5, 2025

(54) DISPLAY APPARATUS

(71) Applicant: Samsung Display Co., LTD., Yongin-si (KR)

(72) Inventors: Seungjun LEE, Yongin-si (KR); Jaewoo LEE, Yongin-si (KR); Sungeun LEE, Yongin-si (KR); Yongsu Lee, Yongin-si (KR)

(21) Appl. No.: 18/963,960

(22) Filed: Nov. 29, 2024

(30) Foreign Application Priority Data
Dec. 1, 2023 (KR) 10-2023-0172734

(51) Int. Cl. H10K 59/121; G09G 3/3233; H10K 59/131

(52) U.S. Cl. CPC H10K 59/1213; G09G 3/3233; H10K 59/131; G09G 2300/0426; G09G 2300/0465; G09G 2300/0819; G09G 2300/0852

(57) ABSTRACT

Pixel circuits may be symmetrically arranged with respect to a boundary between neighboring pixels. Neighboring pixels may have pixel circuits which are symmetric to each other and may share at least one transistor and at least one contact area. Accordingly, a high-resolution display apparatus is provided which may be implemented by increasing integration efficiency of a pixel circuit and increasing pixel density.

This application claims priority to Korean Patent Application No. 10-2023-0172734, filed on Dec. 1, 2023, and all the benefits accruing therefrom under 35 U.S.C. § 119, the content of which in its entirety is herein incorporated by reference.

### BACKGROUND

### 1. Field

One or more embodiments relate to a pixel and a display apparatus including the same.

### 2. Description of the Related Art

Recently, display apparatuses have been used in a greater variety of ways. In addition, as display apparatuses have become thinner and lighter, the range of use for the display apparatuses has widened.

As display apparatuses may be used in various ways, various methods may be used to design the forms of display apparatuses, and the number of functions that may be connected or linked to display apparatuses has been increasing.

### SUMMARY

One or more embodiments provide a high-resolution display apparatus. However, such a technical problem is an example, and one or more embodiments are not limited thereto.

Additional aspects will be set forth in part in the description which follows and, in part, will be apparent from the description, or may be learned by practice of the presented embodiments of the disclosure.

According to one or more embodiments, a display apparatus includes a plurality of pixels, wherein each of the plurality of pixels includes a first transistor, a second transistor connected to a data line, a third transistor connected to a gate of the first transistor and a second terminal of the first transistor, a fourth transistor connected to the gate of the first transistor and a first initialization voltage line, a fifth transistor connected to the second transistor and a reference voltage line wherein the fifth transistor includes a first sub-transistor, and a capacitor connected to the gate of the first transistor and the second transistor. The plurality of pixels include a first pixel and a second pixel adjacent to the first pixel. The fifth transistor included in the first pixel and the fifth transistor included in the second pixel include a second sub-transistor shared by the first pixel and the second pixel. The second sub-transistor shared by the first pixel and the second pixel is connected in series with the first sub-transistor of the fifth transistor of the first pixel and is closer to the reference voltage line than the first sub-transistor of the fifth transistor of the first pixel. The second sub-transistor shared by the first pixel and the second pixel is connected in series with the first sub-transistor of the fifth transistor of the second pixel and is closer to the reference voltage line than the first sub-transistor of the fifth transistor of the second pixel.

According to one or more embodiments, the first pixel and the second pixel may share a contact area where the second sub-transistor is connected to the reference voltage line.

According to one or more embodiments, the second sub-transistor may be arranged at a boundary between the first pixel and the second pixel, wherein an arrangement of transistors of the first pixel, other than the second sub-transistor, and an arrangement of transistors of the second pixel, other than the second sub-transistor, may be symmetric to each other with respect to the boundary between the first pixel and the second pixel.

According to one or more embodiments, the first pixel and the second pixel may share a sixth transistor connected to a driving voltage line, and the sixth transistor shared by the first pixel and the second pixel may be connected to a first terminal of the first transistor of the first pixel and a first terminal of the first transistor of the second pixel.

According to one or more embodiments, the sixth transistor shared by the first pixel and the second pixel may be arranged at a boundary between the first pixel and the second pixel, wherein an arrangement of transistors of the first pixel, other than the sixth transistor, and an arrangement of transistors of the second pixel, other than the sixth transistor, may be symmetric to each other with respect to the boundary between the first pixel and the second pixel.

According to one or more embodiments, the first pixel and the second pixel may share a seventh transistor connected to a bias voltage line, and the seventh transistor shared by the first pixel and the second pixel may be connected to a first terminal of the first transistor of the first pixel and a first terminal of the first transistor of the second pixel.

According to one or more embodiments, the seventh transistor shared by the first pixel and the second pixel may be arranged at a boundary between the first pixel and the second pixel, wherein an arrangement of transistors of the first pixel, other than the seventh transistor, and an arrangement of transistors of the second pixel, other than the seventh transistor, may be symmetric to each other with respect to the boundary between the first pixel and the second pixel.

According to one or more embodiments, the fourth transistor may include a first sub-transistor, wherein the plurality of pixels may further include a third pixel adjacent to the second pixel, wherein the fourth transistor included in the second pixel and the fourth transistor included in the third pixel may further include a second sub-transistor shared by the second pixel and the third pixel. The second sub-transistor shared by the second pixel and the third pixel may be connected in series with the first sub-transistor of the fourth transistor of the second pixel and be closer to the first initialization voltage line than the first sub-transistor of the fourth transistor of the second pixel. The second sub-transistor shared by the second pixel and the third pixel may be connected in series with the first sub-transistor of the fourth transistor of the third pixel and be closer to the first initialization voltage line than the first sub-transistor of the fourth transistor of the third pixel.

According to one or more embodiments, the second sub-transistor of the fourth transistor may be arranged at a boundary between the second pixel and the third pixel, wherein an arrangement of transistors of the second pixel, other than the second sub-transistor of the fourth transistor, and an arrangement of transistors of the third pixel, other than the second sub-transistor of the fourth transistor, may be symmetric to each other with respect to the boundary between the second pixel and the third pixel.

According to one or more embodiments, each of the plurality of pixels may further include an eighth transistor connected to the second terminal of the first transistor and a light-emitting element, and a ninth transistor connected to the light-emitting element and a second initialization voltage line, wherein the plurality of pixels may further include a third pixel adjacent to the second pixel, and wherein the second pixel and the third pixel may share a contact area where the ninth transistor of the second pixel and the ninth transistor of the third pixel are connected to the second initialization voltage line.

According to one or more embodiments, a display apparatus includes a plurality of pixels, wherein each of the plurality of pixels includes a first transistor, a second transistor connected to a data line, a third transistor connected to a gate of the first transistor and a second terminal of the first transistor, a fourth transistor connected to the gate of the first transistor and a first initialization voltage line, a fifth transistor connected to the second transistor and a reference voltage line, and a capacitor connected to the gate of the first transistor and the second transistor. The plurality of pixels include a first pixel and a second pixel adjacent to the first pixel, wherein the first pixel and the second pixel share a sixth transistor connected to a bias voltage line, and wherein the sixth transistor shared by the first pixel and the second pixel is connected to a first terminal of the first transistor of the first pixel and a first terminal of the first transistor of the second pixel.

According to one or more embodiments, the sixth transistor shared by the first pixel and the second pixel may be arranged at a boundary between the first pixel and the second pixel, wherein an arrangement of transistors of the first pixel, other than the sixth transistor, and an arrangement of transistors of the second pixel, other than the sixth transistor, may be symmetric to each other with respect to the boundary between the first pixel and the second pixel.

According to one or more embodiments, the first pixel and the second pixel share a seventh transistor connected to a driving voltage line, and wherein the seventh transistor shared by the first pixel and the second pixel may be connected to the first terminal of the first transistor of the first pixel and the first terminal of the first transistor of the second pixel.

According to one or more embodiments, the seventh transistor shared by the first pixel and the second pixel may be arranged at a boundary between the first pixel and the second pixel, wherein an arrangement of transistors of the first pixel, other than the seventh transistor, and an arrangement of transistors of the second pixel, other than the seventh transistor, may be symmetric to each other with respect to the boundary between the first pixel and the second pixel.

According to one or more embodiments, the first pixel and the second pixel may share a contact area where the fifth transistor of the first pixel and the fifth transistor of the second pixel are connected to the reference voltage line.

According to one or more embodiments, the fifth transistor included in the first pixel and the fifth transistor included in the second pixel may each include a first sub-transistor, and the fifth transistor included in the first pixel and the fifth transistor included in the second pixel may further include a second sub-transistor shared by the first pixel and the second pixel. The second sub-transistor shared by the first pixel and the second pixel may be connected in series with the first sub-transistor of the fifth transistor of the first pixel and be closer to the reference voltage line than the first sub-transistor of the fifth transistor of the first pixel. The second sub-transistor shared by the first pixel and the second pixel may be connected in series with the first sub-transistor of the fifth transistor of the second pixel and be closer to the reference voltage line than the first sub-transistor of the fifth transistor of the second pixel.

According to one or more embodiments, the first pixel and the second pixel may share a contact area where the second sub-transistor is connected to the reference voltage line.

According to one or more embodiments, the second sub-transistor may be arranged at a boundary between the first pixel and the second pixel, wherein an arrangement of transistors of the first pixel, other than the second sub-transistor, and an arrangement of transistors of the second pixel, other than the second sub-transistor, may be symmetric to each other with respect to the boundary between the first pixel and the second pixel.

According to one or more embodiments, the fourth transistor may include a first sub-transistor, wherein the plurality of pixels may further include a third pixel adjacent to the second pixel, wherein the fourth transistor included in the second pixel and the fourth transistor included in the third pixel may further include a second sub-transistor shared by the second pixel and the third pixel. The second sub-transistor shared by the second pixel and the third pixel may be connected in series with the first sub-transistor of the fourth transistor of the second pixel and be closer to the first initialization voltage line than the first sub-transistor of the fourth transistor of the second pixel. The second sub-transistor shared by the second pixel and the third pixel may be connected in series with the first sub-transistor of the fourth transistor of the third pixel and be closer to the first initialization voltage line than the first sub-transistor of the fourth transistor of the third pixel.

According to one or more embodiments, the second sub-transistor of the fourth transistor may be arranged at a boundary between the second pixel and the third pixel, wherein an arrangement of transistors of the second pixel, other than the second sub-transistor of the fourth transistor, and an arrangement of transistors of the third pixel, other than the second sub-transistor of the fourth transistor, may be symmetric to each other with respect to the boundary between the second pixel and the third pixel.

According to one or more embodiments, each of the plurality of pixels may further include a seventh transistor connected to a driving voltage line, an eighth transistor connected to the second terminal of the first transistor and a light-emitting element, and a ninth transistor connected to the light-emitting element and a second initialization voltage line, wherein the plurality of pixels may further include a third pixel adjacent to the second pixel, wherein the second pixel and the third pixel may share a contact area where the ninth transistor of the second pixel and the ninth transistor of the third pixel are connected to the second initialization voltage line.

### BRIEF DESCRIPTION OF THE DRAWINGS

The above and other aspects, features, and advantages of certain embodiments of the disclosure will be more apparent from the following description taken in conjunction with the accompanying drawings, in which:

FIGS. 1A and 1B are schematic diagrams of a display apparatus according to an embodiment;

FIG. 2 is a schematic diagram of a display apparatus according to an embodiment;

FIGS. 3 to 5 are schematic diagrams of a pixel according to an embodiment;

FIGS. 6A and 6B are diagrams schematically illustrating sharing of a transistor between adjacent pixels according to an embodiment;

FIGS. 7A and 7B are diagrams schematically illustrating sharing of a transistor between adjacent pixels according to an embodiment;

FIG. 8 is a diagram schematically illustrating sharing of a transistor between adjacent pixels according to an embodiment;

FIGS. 9 to 11 are diagrams schematically illustrating sharing of a transistor between adjacent pixels according to an embodiment;

FIG. 12 is a diagram schematically illustrating positions of transistors and capacitors of pixels according to an embodiment;

FIGS. 13 to 19 are diagrams schematically illustrating elements of the pixels of FIG. 12 layer by layer;

FIG. 20 is a cross-sectional view of a region of FIG. 12, taken along a line I-I′ of FIG. 12;

FIGS. 21 to 23 are schematic diagrams of a pixel according to an embodiment; and

FIG. 24 is a diagram schematically illustrating sharing of a transistor between adjacent pixels according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described herein, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the present description allows for various changes and numerous embodiments, certain embodiments will be illustrated in the drawings and described in the written description. Effects and features of one or more embodiments and methods of accomplishing the same will become apparent from the following detailed description of the one or more embodiments, taken in conjunction with the accompanying drawings. However, the present embodiments may have different forms and should not be construed as being limited to the descriptions set forth herein.

While such terms as “first” and “second” may be used to describe various elements, such elements must not be limited to the above terms. The above terms are used to distinguish one element from another.

The singular forms “a,” “an,” and “the” as used herein are intended to include the plural forms as well unless the context clearly indicates otherwise.

It will be understood that the terms “include,” “comprise,” and “have” as used herein specify the presence of stated features or elements but do not preclude the addition of one or more other features or elements.

It will be further understood that, when a layer, region, or element is referred to as being on another layer, region, or element, the layer, region, or element may be directly or indirectly on the other layer, region, or element. That is, for example, intervening layers, regions, or elements may be present.

Sizes of elements in the drawings may be exaggerated or reduced for convenience of explanation. For example, since sizes and thicknesses of elements in the drawings are arbitrarily illustrated for convenience of explanation, the following embodiments are not limited thereto.

As used herein, the expression “A and/or B” refers to A, B, or A and B. In some aspects, the expression “at least one of A and B” refers to A, B, or A and B.

As used herein, descriptions in which X and Y are connected may include the case where X and Y are physically connected, the case where X and Y are functionally connected, and the case where X and Y are electrically connected. In some aspects, when descriptions in which X and Y are connected may include the case where X and Y are directly connected or the case where X and Y are indirectly connected with another element disposed therebetween. In this regard, X and Y may include elements (e.g. apparatuses, devices, circuits, wirings, electrodes, terminals, films, layers, regions, or the like).

For example, the case where X and Y are electrically connected may include the case where X and Y are directly electrically connected and/or the case where X and Y are indirectly electrically connected with another element disposed therebetween. The case where X and Y are indirectly electrically connected may include the case where at least one device (e.g. a switch, a transistor, a capacitor, an inductor, a resistor, a diode, or the like) that enables electrical connection of X and Y is connected between X and Y. Therefore, connection is not limited to a preset connection relationship, for example, not limited to a connection relationship illustrated in the drawings or detailed descriptions, and may include other connection relationships not illustrated in the drawings or detailed descriptions.

As used herein, the term “ON” used in association with the state of a device may denote an activated state of the device, and the term “OFF” may denote an inactivated state of the device. The term “ON” used in association with a signal received by a device may denote a signal activating the device, and the term “OFF” may denote a signal inactivating the device. A device may be activated by a high-level voltage or a low-level voltage. For example, a P-channel transistor (a P-type transistor) is activated by a low-level voltage, and an N-channel transistor (an N-type transistor) is activated by a high-level voltage. Therefore, it should be understood that “ON” voltages for a P-type transistor and an N-type transistor are opposite (low versus high) voltage levels.

The direction x, the direction y, and the direction z are not limited to directions along three axes of the rectangular coordinate system and may be interpreted in a broader sense. For example, the direction x, the direction y, and the direction z may be perpendicular to one another or may represent different directions that are not perpendicular to one another.

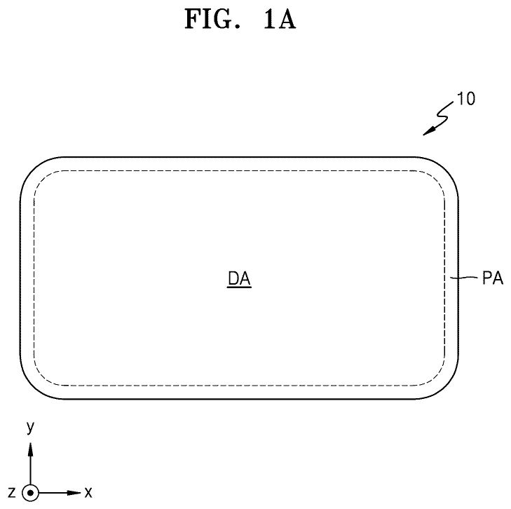

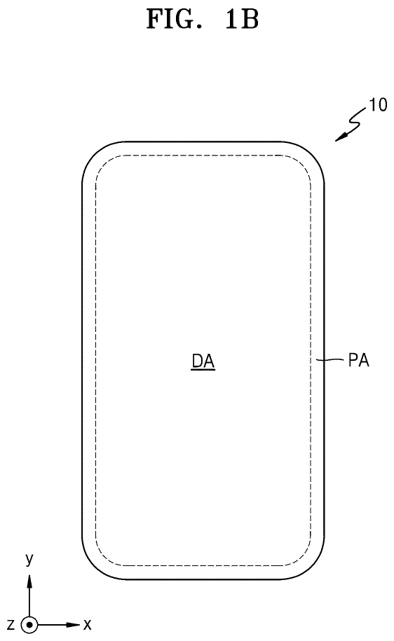

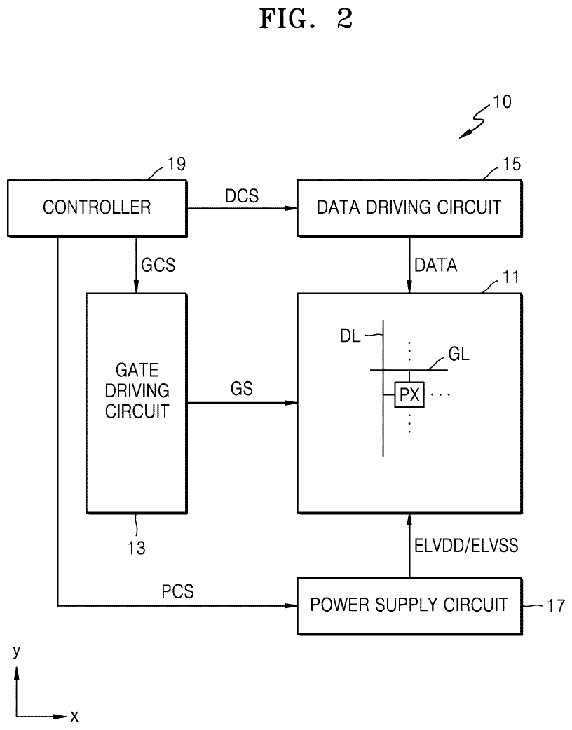

FIGS. 1A and 1B are schematic diagrams of a display apparatus 10 according to an embodiment. FIG. 2 is a schematic diagram of the display apparatus 10 according to an embodiment.

Referring to FIGS. 1A and 1B, the display apparatus 10 may include a display area DA displaying an image and a peripheral area PA outside the display area DA. The display area DA may be entirely surrounded by the peripheral area PA.

In a plan view of the display area DA, the display area DA may have a rectangular shape. In another embodiment, the display area DA may have a polygonal shape, such as, for example, a triangle, a pentagon, or a hexagon, a circular shape, an oval shape, or an atypical shape. Corners of edges of the display area DA may have round shapes. In an embodiment, the display area DA in the display apparatus 10 may have a length in the direction x greater than a length in the direction y as illustrated in FIG. 1A. In another embodiment, the display area DA in the display apparatus 10 may have a length in the direction y greater than a length in the direction x as illustrated in FIG. 1B. The direction z may be perpendicular to the direction x and direction y.

Referring to FIG. 2, the display apparatus 10 according to an embodiment may include a pixel area 11, a gate driving circuit 13, a data driving circuit 15, a power supply circuit 17, and a controller 19.

The pixel area 11 may correspond to the display area DA. As illustrated in FIG. 2, a plurality of gate lines GL, a plurality of data lines DL, and a plurality of pixels PX connected thereto may be arranged in the pixel area 11. The plurality of pixels PX may be arranged in various forms, such as, for example, a stripe arrangement, a PenTile® arrangement, a diamond arrangement, and a mosaic arrangement, to display an image. Each pixel PX may include an organic light-emitting diode (OLED) as a display element (a light-emitting element), and the organic light-emitting diode (OLED) may be connected to a pixel circuit. The pixel PX may emit, for example, red, green, blue, or white light through the organic light-emitting diode (OLED). Each pixel PX may be connected to at least one corresponding gate line among the plurality of gate lines GL and at least one corresponding data line among the plurality of data lines DL.

The pixel circuit may include a plurality of transistors and at least one capacitor. In an embodiment, the plurality of transistors included in the pixel circuit may be P-type silicon thin-film transistors. In another embodiment, the plurality of transistors included in the pixel circuit may be N-type oxide thin-film transistors. In another embodiment, some of the plurality of transistors included in the pixel circuit may be an N-type oxide thin-film transistor, and some of the plurality of transistors included in the pixel circuit may be a P-type silicon thin-film transistor.

A silicon thin-film transistor may be a thin-film transistor in which a semiconductor layer includes amorphous silicon, polysilicon (e.g., a low-temperature polycrystalline silicon (LTPS)), or the like. An oxide thin-film transistor may be a low-temperature polycrystalline oxide (LTPO) thin-film transistor in which a semiconductor layer includes oxide. However, this is an example, and N-type transistors are not limited thereto. For example, a semiconductor layer included in the N-type transistor may include an inorganic semiconductor (e.g., amorphous silicon, polysilicon) or an organic semiconductor.

Each of the gate lines GL may extend in the direction x (a row direction) and may be connected to pixels PX located in the same row. The gate line GL may be configured to transmit a gate signal to the pixels PX of the same row. Each of the data lines DL may extend in the direction y (a column direction) and may be connected to pixels PX located in the same column. Each data line DL may be configured to transmit a data signal to each of the pixels PX of the same column in synchronization with the gate signal.

In an embodiment, the peripheral area PA may be a non-display area in which pixels PX are not arranged. Various conductive lines may be in the peripheral area PA and may be configured to transmit an electric signal which will be applied to the pixel area 11, outer circuits electrically connected to pixel circuits, and pads on which a printed circuit board or a driver integrated circuit (IC) chip is attached. For example, the gate driving circuit 13, the data driving circuit 15, the power supply circuit 17, and the controller 19 may be provided in the peripheral area PA.

The gate driving circuit 13 may be connected to the plurality of gate lines GL and may be configured to generate a gate signal GS in response to a driving control signal GCS from the controller 19 and sequentially supply the gate signal GS to the gate lines GL. The gate line GL may be connected to a gate of a transistor included in the pixel PX. The gate signal GS may be a gate control signal for controlling the turn-on and turn-off of a transistor whose gate is connected to the gate line GL. The gate signal GS may be a square wave signal including a gate-on voltage at which the transistor may be turned on and a gate-off voltage at which the transistor may be turned off. In an embodiment, the gate-on voltage may be a high-level voltage or a low-level voltage.

Although FIG. 2 illustrates the pixel PX connected to one gate line GL, this is an example, and the pixel PX may be connected to two or more gate lines, and the gate driving circuit 13 may be configured to supply two or more gate signals to the corresponding gate lines, and timings of the two or more gate signals at which the gate-on voltage is applied may be different from each other.

The data driving circuit 15 may be connected to the plurality of data lines DL and may be configured to supply a data signal DATA to the data lines DL in response to a driving control signal DCS from the controller 19. The data signal DATA supplied to the data line DL may be supplied to the pixel PX to which the gate signal GS is supplied. The data driving circuit 15 may be configured to convert input image data having a gray scale input from the controller 19 into the data signal DATA in the form of voltage or current.

The power supply circuit 17 may be configured to generate voltages associated with driving the pixel PX in response to a driving control signal PCS from the controller 19. The power supply circuit 17 may be configured to generate a driving voltage ELVDD and a common voltage ELVSS and supply the same to the pixels PX. The driving voltage ELVDD may be a high-level voltage which is provided to one terminal of a driving transistor connected to a first electrode (a pixel electrode or an anode) of the display element included in the pixel PX. The common voltage ELVSS may be a low-level voltage which is provided to a second electrode (an opposite electrode or a cathode) of the display element included in the pixel PX.

The controller 19 may generate the driving control signals GCS, DCS, and PCS, based on signals input from the outside, and may supply the same to the gate driving circuit 13, the data driving circuit 15, and the power supply circuit 17. The driving control signal GCS output to the gate driving circuit 13 may include a plurality of clock signals and a gate start signal. The driving control signal DCS output to the data driving circuit 15 may include a plurality of clock signals and a data start signal.

The display apparatus 10 may include a display panel, and the display panel may include a substrate. The pixels PX may be arranged in the display area DA (the pixel area 11) of the substrate. A portion of the gate driving circuit 13 or the entire gate driving circuit 13 may be directly formed in the peripheral area PA of the substrate during a process of forming a transistor that constitutes the pixel circuit in the display area DA of the substrate. The data driving circuit 15, the power supply circuit 17, and the controller 19 may each be formed in the form of an individual IC chip or may be formed together in the form of a single IC chip, and may be disposed on a flexible printed circuit board (FPCB) electrically connected to a pad arranged at one side of the substrate. In another embodiment, the data driving circuit 15, the power supply circuit 17, and the controller 19 may be directly disposed on the substrate in a chip-on-glass (COG) or chip-on-plastic (COP) manner.

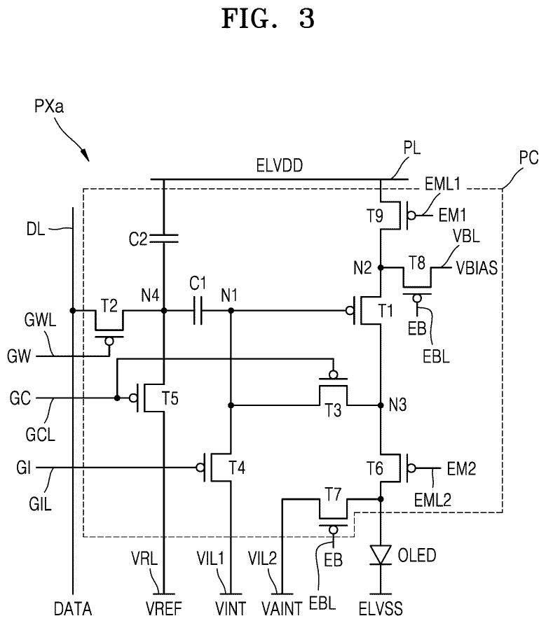

FIGS. 3 to 5 are schematic diagrams of a pixel PXa according to an embodiment.

Referring to FIG. 3, the pixel PXa may include a pixel circuit PC and an organic light-emitting diode OLED as a display element connected to the pixel circuit PC.

The pixel circuit PC of the pixel PXa may include first to ninth transistors T1 to T9, a first capacitor C1, and a second capacitor C2, and the pixel circuit PC may be connected to a plurality of signal lines. The signal lines may include the data line DL, a first gate line GWL, a second gate line GIL, a third gate line GCL, a fourth gate line EML1, a fifth gate line EML2, a sixth gate line EBL, a driving voltage line PL, a reference voltage line VRL, a first initialization voltage line VIL1, a second initialization voltage line VIL2, and a bias voltage line VBL.

The first transistor T1 may be a driving transistor in which the magnitude of a source-drain current is determined according to a gate-source voltage Vgs, and the second to ninth transistors T2 to T9 may be switching transistors which are turned on/turned off according to a gate voltage to transmit a signal. The first to ninth transistors T1 to T9 may be implemented with thin-film transistors. Depending on the type (P-type or N-type) of transistor and/or operation conditions for each of the first to ninth transistors T1 to T9, a first terminal may be a source or drain, and a second terminal may be a terminal different from the first terminal. In an example in which the first terminal is a source, the second terminal may be a drain.

In an example, the first to ninth transistors T1 to T9 may be P-type silicon thin-film transistors, a gate-on voltage of a gate signal for turning on the first to ninth transistors T1 to T9 may be a low-level voltage, and a gate-off voltage of a gate signal for turning off the first to ninth transistors T1 to T9 may be a high-level voltage.

The first transistor T1 may be connected between the driving voltage line PL and the organic light-emitting diode OLED. The first transistor T1 may be connected to the driving voltage line PL via the ninth transistor T9 and may be connected to the organic light-emitting diode OLED via the sixth transistor T6. The first transistor T1 may include a gate connected to a first node N1, a first terminal connected to a second node N2, and a second terminal connected to a third node N3. The first transistor T1 may be configured to receive the data signal DATA according to a switching operation of the second transistor T2 and supply a driving current to the organic light-emitting diode OLED.

The second transistor T2 may be connected between the data line DL and the first node N1. The second transistor T2 may be connected between the data line DL and a fourth node N4. The second transistor T2 may include a gate connected to the first gate line GWL, a first terminal connected to the data line DL, and a second terminal connected to the fourth node N4. The second transistor T2 may be turned on according to a first gate signal GW received through the first gate line GWL to perform a switching operation for transmitting the data signal DATA transmitted to the data line DL to the fourth node N4.

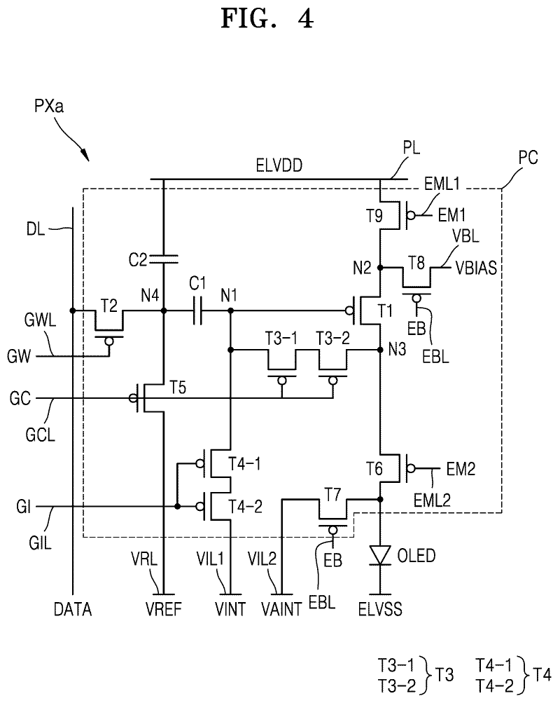

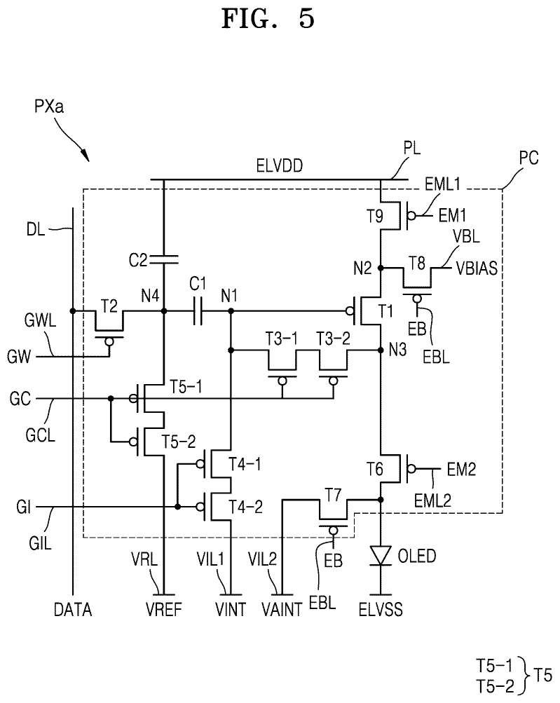

The third transistor T3 may be connected between the third node N3 and the first node N1. The third transistor T3 may be connected to the organic light-emitting diode OLED via the sixth transistor T6. The third transistor T3 may include a gate connected to the third gate line GCL, a first terminal connected to the third node N3, and a second terminal connected to the first node N1. The third transistor T3 may be turned on according to a third gate signal GC received through the third gate line GCL to diode-connect the first transistor T1 and compensate for a threshold voltage of the first transistor T1. In an embodiment, as illustrated in FIGS. 4 and 5, the third transistor T3 may be a dual gate transistor in which a pair of sub-transistors (e.g., a first sub-transistor T3-1 and a second sub-transistor T3-2) are connected in series. Gates of the first sub-transistor T3-1 and the second sub-transistor T3-2 may be connected to the third gate line GCL.

The fourth transistor T4 may be connected between the first node N1 and the first initialization voltage line VIL1. The fourth transistor T4 may include a gate connected to the second gate line GIL, a first terminal connected to the first node N1, and a second terminal connected to the first initialization voltage line VIL1. The fourth transistor T4 may be turned on according to a second gate signal GI received through the second gate line GIL to initialize the gate of the first transistor T1 with a first initialization voltage VINT. In an embodiment, as illustrated in FIGS. 4 and 5, the fourth transistor T4 may be a dual gate transistor in which a pair of sub-transistors (e.g., a first sub-transistor T4-1 and a second sub-transistor T4-2) are connected in series. Gates of the first sub-transistor T4-1 and the second sub-transistor T4-2 may be connected to the second gate line GIL.

The fifth transistor T5 may be connected between the fourth node N4 and the reference voltage line VRL. The fifth transistor T5 may include a gate connected to the third gate line GCL, a first terminal connected to the reference voltage line VRL, and a second terminal connected to the fourth node N4. The fifth transistor T5 may be turned on according to the third gate signal GC received through the third gate line GCL to transmit a reference voltage VREF to the fourth node N4. In an embodiment, as illustrated in FIG. 5, the fifth transistor T5 may be a dual gate transistor in which a pair of sub-transistors (e.g., a first sub-transistor T5-1 and a second sub-transistor T5-2) are connected in series. Gates of the first sub-transistor T5-1 and the second sub-transistor T5-2 may be connected to the third gate line GCL.

The sixth transistor T6 may be connected between the third node N3 and the organic light-emitting diode OLED. The sixth transistor T6 may include a gate connected to the fifth gate line EML2, a first terminal connected to the third node N3, and a second terminal connected to a pixel electrode of the organic light-emitting diode OLED. The sixth transistor T6 may be turned on according to a fifth gate signal EM2 received through the fifth gate line EML2.

The seventh transistor T7 may be connected between the organic light-emitting diode OLED and the second initialization voltage line VIL2. The seventh transistor T7 may include a gate connected to the sixth gate line EBL, a first terminal connected to the second terminal of the sixth transistor T6 and the pixel electrode of the organic light-emitting diode OLED, and a second terminal connected to the second initialization voltage line VIL2. The seventh transistor T7 may be turned on according to a sixth gate signal EB received through the sixth gate line EBL to transmit a second initialization voltage VAINT to the pixel electrode of the organic light-emitting diode OLED and initialize the pixel electrode of the organic light-emitting diode OLED.

The eighth transistor T8 may be connected between the second node N2 and the bias voltage line VBL. The eighth transistor T8 may include a gate connected to the sixth gate line EBL, a first terminal connected to the bias voltage line VBL, and a second terminal connected to the second node N2. The eighth transistor T8 may be turned on according to the sixth gate signal EB received through the sixth gate line EBL to transmit a bias voltage VBIAS to the first terminal of the first transistor T1 and control the gate-source voltage Vgs of the first transistor T1. By controlling the gate-source voltage Vgs of the first transistor T1, a threshold voltage of the first transistor T1 may be shifted. Accordingly, a change in voltage-current characteristics due to hysteresis characteristics of the first transistor T1 may be compensated for.

The ninth transistor T9 may be connected between the driving voltage line PL and the second node N2. The ninth transistor T9 may include a gate connected to the fourth gate line EML1, a first terminal connected to the driving voltage line PL, and a second terminal connected to the second node N2. The ninth transistor T9 may be turned on according to a fourth gate signal EM1 received through the fourth gate line EML1. In an example in which the sixth transistor T6 and the ninth transistor T9 are both in an activated state (e.g., are turned on simultaneously), a current path from the driving voltage line PL to the organic light-emitting diode OLED may be formed. The first transistor T1 may be configured to output a driving current corresponding to the data signal DATA stored in the first capacitor C1.

The first capacitor C1 may be connected between the first node N1 and the fourth node N4. The first capacitor C1 may be charged with voltages corresponding to a threshold voltage of the first transistor T1 and the data signal DATA. The second capacitor C2 may be connected between the driving voltage line PL and the fourth node N4.

The organic light-emitting diode OLED may include a pixel electrode (e.g., an anode) and an opposite electrode (e.g., a cathode) facing the pixel electrode, and the opposite electrode may receive the common voltage ELVSS. The organic light-emitting diode OLED may receive the driving current corresponding to the data signal DATA from the first transistor T1 and emit light of a certain color, thereby displaying an image.

According to an embodiment, at least one of the third transistor T3, the fourth transistor T4, and the fifth transistor T5 may be a dual gate transistor, and thus, leakage current may be prevented by reducing off-current during turn-off, which may support stably maintaining a data signal in the first capacitor C1.

According to an embodiment, neighboring pixels may share one of the sub-transistors of at least one of the fourth transistor T4 and the fifth transistor T5, which may support efficiently using a space where pixel circuits are arranged and thus implementing a high-resolution display apparatus. For example, neighboring pixels may share a sub-transistor which is located relatively close to a power source among the sub-transistors of at least one of the fourth transistor T4 and the fifth transistor T5.

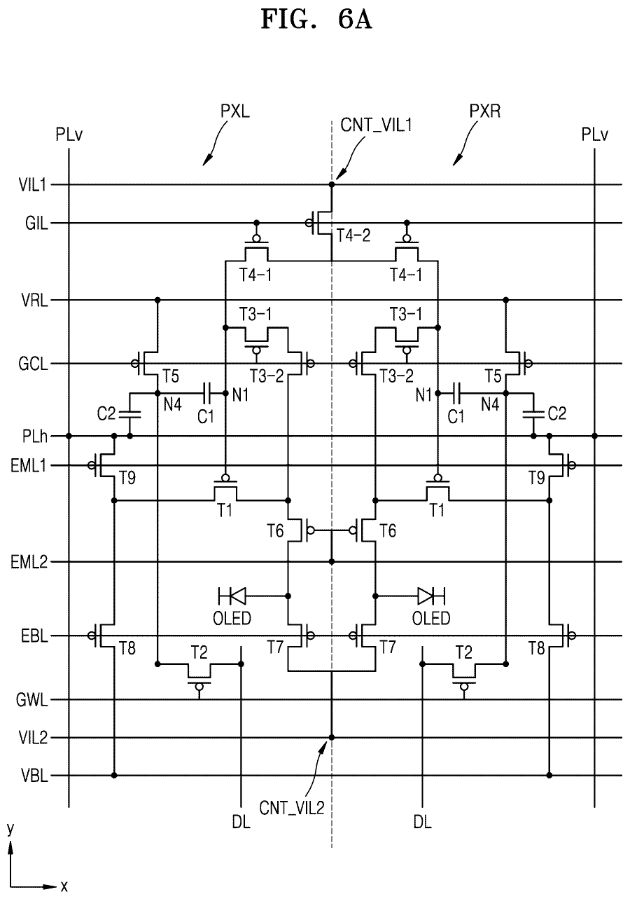

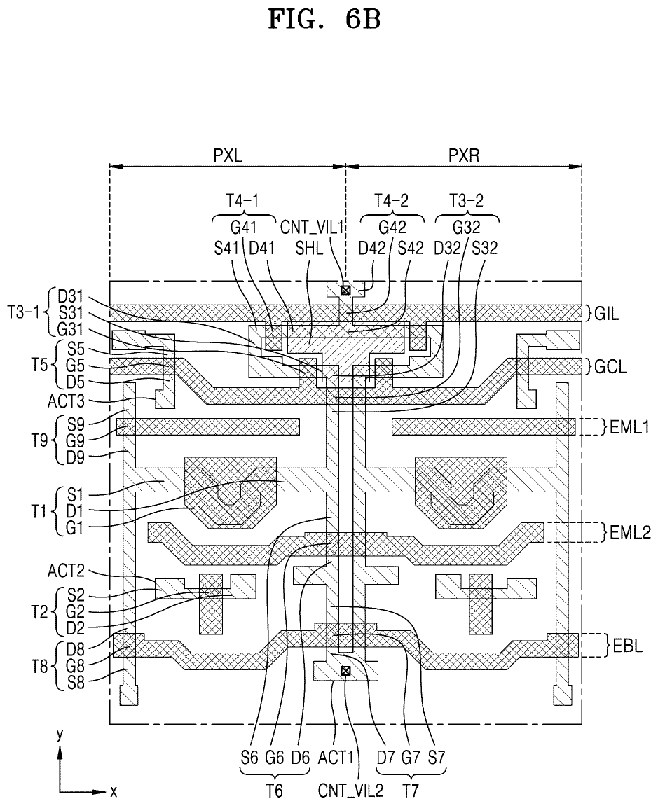

In an embodiment, two neighboring pixels may share the second sub-transistor T4-2 of the fourth transistor T4 and thus may share a contact area connecting the second sub-transistor T4-2 to the first initialization voltage line VIL1, an example of which is later described herein at least with reference to FIG. 6A. Expressed another way, respective fourth transistors T4 of neighboring pixels may share a second sub-transistor T4-2.

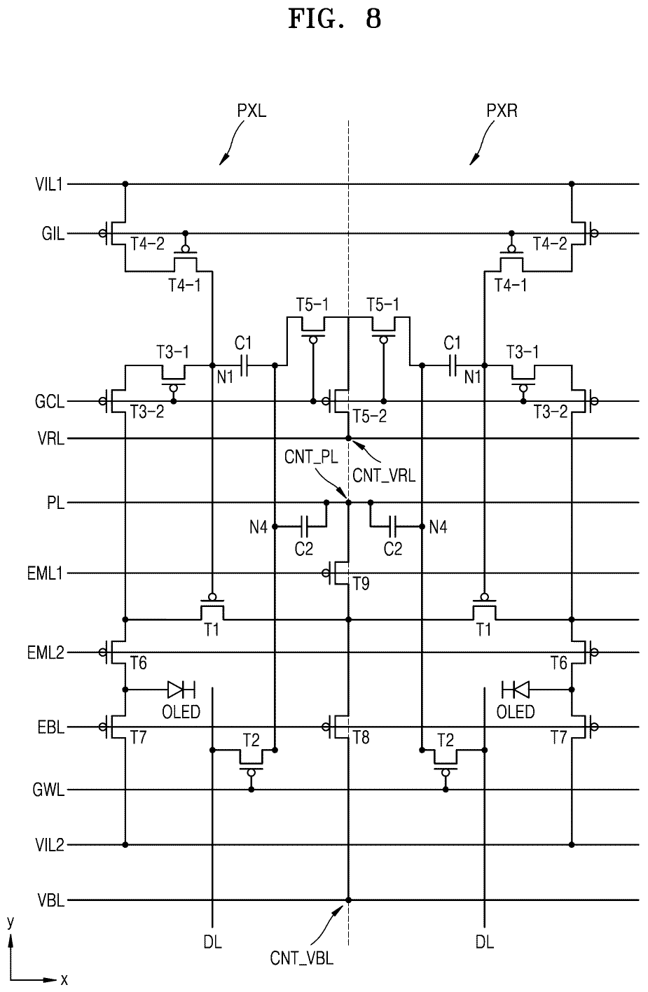

In an embodiment, two neighboring pixels may share the second sub-transistor T5-2 of the fifth transistor T5 and thus may share a contact area connecting the second sub-transistor T5-2 to the reference voltage line VRL, an example of which is later described herein at least with reference to FIG. 8. Expressed another way, respective fifth transistors T5 of neighboring pixels may share a second sub-transistor T5-2.

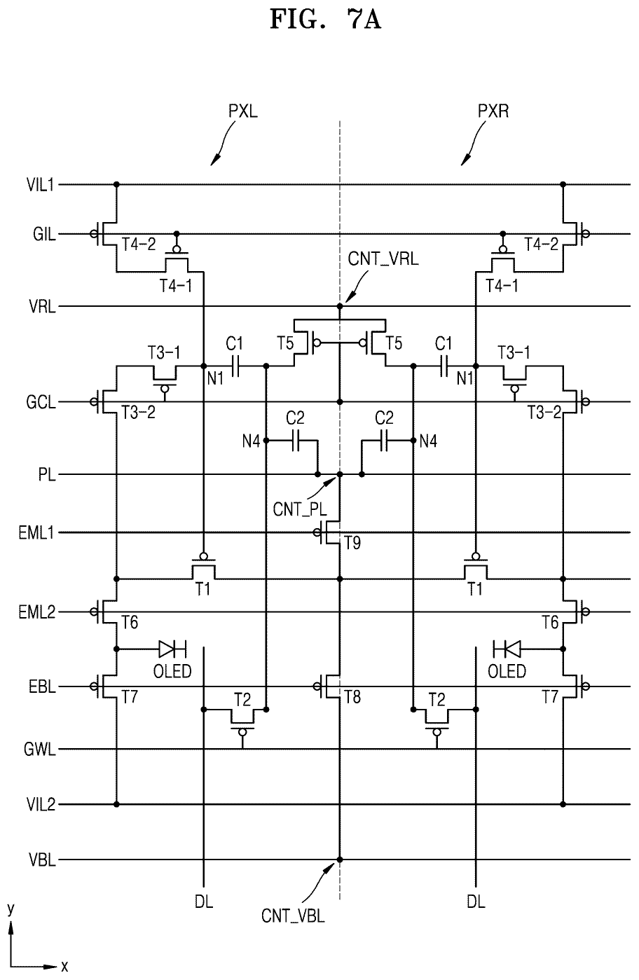

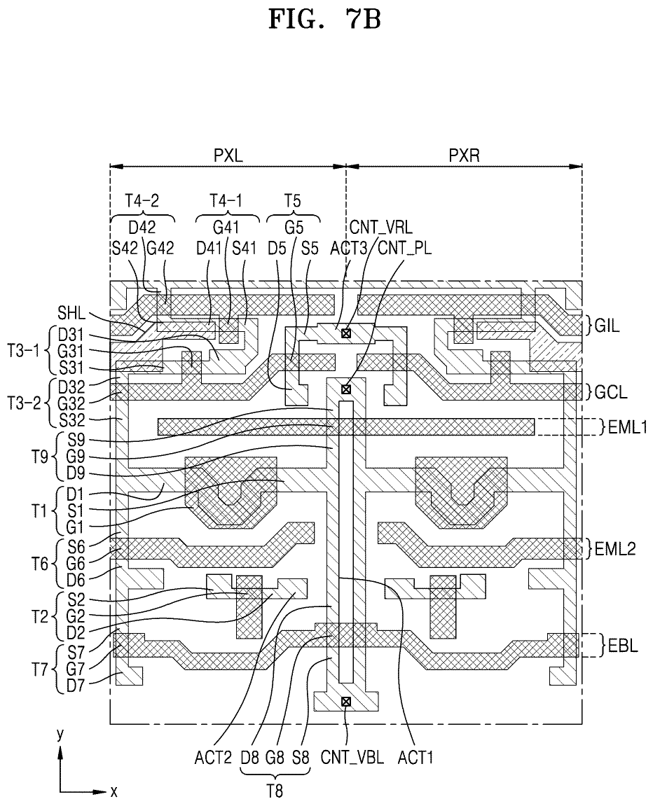

According to an embodiment, neighboring pixels may share at least one transistor (e.g., at least one of the seventh transistor T7, the eighth transistor T8, and the ninth transistor T9) constituting a pixel circuit, thereby efficiently using a space where pixel circuits are arranged and thus implementing a high-resolution display apparatus, example aspects of which are described herein at least with reference to FIGS. 7A and 8.

In an embodiment, two neighboring pixels may share the seventh transistor T7 and thus may share a contact area connecting the seventh transistor T7 to the second initialization voltage line VIL2. In an embodiment, two neighboring pixels may share the eighth transistor T8 and thus may share a contact area connecting the eighth transistor T8 to the bias voltage line VBL. In an embodiment, two neighboring pixels may share the ninth transistor T9 and thus may share a contact area connecting the ninth transistor T9 to the driving voltage line PL.

According to an embodiment, neighboring pixels may share a contact area connecting at least one transistor constituting a pixel circuit to a voltage line, thereby efficiently using a space where pixel circuits are arranged and thus implementing a high-resolution display apparatus.

In an embodiment, two neighboring pixels may each include the seventh transistor T7 and may share a contact area connecting the seventh transistor T7 to the second initialization voltage line VIL2. In an embodiment, two neighboring pixels may each include the eighth transistor T8 and may share a contact area connecting the eighth transistor T8 to the bias voltage line VBL. In an embodiment, two neighboring pixels may each include the ninth transistor T9 and may share a contact area connecting the ninth transistor T9 to the driving voltage line PL.

FIGS. 6A and 6B are diagrams schematically illustrating sharing of a transistor between adjacent pixels according to an embodiment. FIGS. 6A and 6B are diagrams schematically illustrating sharing of a fourth transistor between adjacent pixels. FIG. 6A is a diagram illustrating the pixel illustrated in FIG. 4. FIG. 6B is a diagram schematically illustrating the transistors in the pixel illustrated in FIG. 4.

Referring to FIG. 6A, a left pixel PXL and a right pixel PXR adjacent to each other in the direction x (a row direction) may share the second sub-transistor T4-2 of the fourth transistor T4. Expressed another way, respective fourth transistors T4 of the left pixel PXL and the right pixel PXR may share a second sub-transistor T4-2.

The second sub-transistor T4-2 of the fourth transistor T4 may be arranged between the left pixel PXL and the right pixel PXR, for example, in a boundary area of the left pixel PXL and the right pixel PXR. The second sub-transistor T4-2 may be connected between the first sub-transistor T4-1 of the left pixel PXL and the first initialization voltage line VIL1 and may be connected between the first sub-transistor T4-1 of the right pixel PXR and the first initialization voltage line VIL1. The second sub-transistor T4-2 may be closer to the first initialization voltage line VIL1 than the first sub-transistor T4-1 of the left pixel PXL. The second sub-transistor T4-2 may be closer to the first initialization voltage line VIL1 than the first sub-transistor T4-1 of the right pixel PXR.

With respect to a boundary between the left pixel PXL and the right pixel PXR, the first to ninth transistors T1 to T9 and the first and second capacitors C1 and C2 of the left pixel PXL and the first to ninth transistors T1 to T9 and the first and second capacitors C1 and C2 of the right pixel PXR may be arranged symmetric to each other.

The first gate line GWL, the second gate line GIL, the third gate line GCL, the fourth gate line EML1, the fifth gate line EML2, the sixth gate line EBL, the reference voltage line VRL, the first initialization voltage line VIL1, the second initialization voltage line VIL2, and the bias voltage line VBL may each extend in the direction x, and the data line DL may extend in the direction y. The driving voltage line PL may include a first driving voltage line PLh extending in the direction x and/or a second driving voltage line PLv extending in the direction y. In an embodiment, the first driving voltage line PLh and the second driving voltage line PLv may be connected to each other, and thus, the driving voltage line PL may have a mesh structure.

The second sub-transistor T4-2 of the fourth transistor T4 may be connected to the first initialization voltage line VIL1 in a contact area CNT_VIL1. The left pixel PXL and the right pixel PXR may share the second sub-transistor T4-2 and may share the contact area CNT_VIL1 connecting the second sub-transistor T4-2 to the first initialization voltage line VIL1.

The left pixel PXL and the right pixel PXR may each include the seventh transistor T7, and the seventh transistor T7 of the left pixel PXL and the seventh transistor T7 of the right pixel PXR may be connected to the second initialization voltage line VIL2 in a contact area CNT_VIL2. The left pixel PXL and the right pixel PXR may share the contact area CNT_VIL2 where the seventh transistor T7 of the left pixel PXL and the seventh transistor T7 of the right pixel PXR are connected to the second initialization voltage line VIL2.

Referring to FIG. 6B, each of the first to ninth transistors T1 to T9 may include a semiconductor layer and a gate electrode (a gate) overlapping the semiconductor layer. The semiconductor layer may include a source region, a drain region, and a channel region between the source region and the drain region, and the gate electrode may overlap the channel region. In some cases, the source region or the drain region may be interpreted as a source electrode (source) or a drain electrode (drain) of a transistor.

Each of the left pixel PXL and the right pixel PXR may include a first semiconductor layer ACT1, a second semiconductor layer ACT2, and a third semiconductor layer ACT3.

The first semiconductor layer ACT1 may include semiconductor layers of the first transistor T1, the third transistor T3, the fourth transistor T4, the sixth transistor T6, the seventh transistor T7, the eighth transistor T8, and the ninth transistor T9. In each of the left pixel PXL and the right pixel PXR, the first semiconductor layer ACT1 of the left pixel PXL and the first semiconductor layer ACT1 of the right pixel PXR may be integrally formed and connected to each other.

The second gate line GIL, the third gate line GCL, the fourth gate line EML1, the fifth gate line EML2, and the sixth gate line EBL may be disposed over the first semiconductor layer ACT1, the second semiconductor layer ACT2, and the third semiconductor layer ACT3 while each extending in the direction x.

The first semiconductor layer ACT1 may include a source region S1 and a drain region D1 of the first transistor T1, source regions S31 and S32 and drain regions D31 and D32 of the third transistor T3, source regions S41 and S42 and drain regions D41 and D42 of the fourth transistor T4, a source region S6 and a drain region D6 of the sixth transistor T6, a source region S7 and a drain region D7 of the seventh transistor T7, a source region S8 and a drain region D8 of the eighth transistor T8, and a source region S9 and a drain region D9 of the ninth transistor T9. The second semiconductor layer ACT2 may include a source region S2 and a drain region D2 of the second transistor T2. The third semiconductor layer ACT3 may include a source region S5 and a drain region D5 of the fifth transistor T5.

Gate electrodes G1 to G9 of the first to ninth transistors T1 to T9 may be disposed over the first semiconductor layer ACT1, the second semiconductor layer ACT2, and the third semiconductor layer ACT3.

The gate electrode G1 of the first transistor T1 may have an island shape. The gate electrode G2 of the second transistor T2 may have an island shape. The gate electrodes G31 and G32 of the third transistor T3 may be portions of the third gate line GCL and may be disposed on the same layer. The gate electrodes G41 and G42 of the fourth transistor T4 may be portions of the second gate line GIL and may be disposed on the same layer. The gate electrode G5 of the fifth transistor T5 may be a portion of the third gate line GCL. The gate electrode G6 of the sixth transistor T6 may be a portion of the fifth gate line EML2. The gate electrode G7 of the seventh transistor T7 may be a portion of the sixth gate line EBL. The gate electrode G8 of the eighth transistor T8 may be a portion of the sixth gate line EBL. The gate electrode G9 of the ninth transistor T9 may be a portion of the fourth gate line EML1.

The drain region D42 of the second sub-transistor T4-2 of the fourth transistor T4 may be connected to the first initialization voltage line VIL1, which will be disposed over the drain region D42 later, through a contact hole in the contact area CNT_VIL1. The left pixel PXL and the right pixel PXR may share the second sub-transistor T4-2 and may share the contact area CNT_VIL1 connecting the second sub-transistor T4-2 to the first initialization voltage line VIL1.

The left pixel PXL and the right pixel PXR may each include the seventh transistor T7, and the drain region D7 of the seventh transistor T7 of the left pixel PXL and the drain region D7 of the seventh transistor T7 of the right pixel PXR may be integrally formed and connected to each other. The left pixel PXL and the right pixel PXR may share the contact area CNT_VIL2 connecting the seventh transistor T7 to the second initialization voltage line VIL2. The drain region D7 of the seventh transistor T7 of the left pixel PXL and the drain region D7 of the seventh transistor T7 of the right pixel PXR may be connected to the second initialization voltage line VIL2, which will be disposed over the drain region D7 later, through a contact hole in the contact area CNT_VIL2.

In an embodiment, a shielding layer SHL covering a semiconductor region (e.g., a semiconductor region between two channel regions) between the gate electrodes G31 and G32 of the third transistor T3 and a semiconductor region (e.g., a semiconductor region between two channel regions) between the gate electrodes G41 and G42 of the fourth transistor T4 may be provided.

FIGS. 7A and 7B are diagrams schematically illustrating sharing of a transistor between adjacent pixels according to an embodiment. FIGS. 7A and 7B are diagrams schematically illustrating sharing of an eighth transistor and a ninth transistor between adjacent pixels. FIG. 7A is a diagram illustrating the pixel illustrated in FIG. 4. FIG. 7B is a diagram schematically illustrating the transistors in the pixel illustrated in FIG. 4.

Referring to FIG. 7A, the left pixel PXL and the right pixel PXR adjacent to each other in the direction x (a row direction) may share the eighth transistor T8 and the ninth transistor T9.

The eighth transistor T8 and the ninth transistor T9 may be arranged between the left pixel PXL and the right pixel PXR, for example, in a boundary area of the left pixel PXL and the right pixel PXR. The left pixel PXL and the right pixel PXR may share a contact area CNT_VBL where the eighth transistor T8 is connected to the bias voltage line VBL. The left pixel PXL and the right pixel PXR may share a contact area CNT_PL where the ninth transistor T9 is connected to the driving voltage line PL.

With respect to a boundary between the left pixel PXL and the right pixel PXR, the first to seventh transistors T1 to T7 and the first and second capacitors C1 and C2 of the left pixel PXL and the first to seventh transistors T1 to T7 and the first and second capacitors C1 and C2 of the right pixel PXR may be arranged symmetric to each other. The left pixel PXL and the right pixel PXR may each include the fourth transistor T4, and the fourth transistor T4 may include the first sub-transistor T4-1 and the second sub-transistor T4-2.

The first gate line GWL, the second gate line GIL, the third gate line GCL, the fourth gate line EML1, the fifth gate line EML2, the sixth gate line EBL, the driving voltage line PL, the reference voltage line VRL, the first initialization voltage line VIL1, the second initialization voltage line VIL2, and the bias voltage line VBL may each extend in the direction x, and the data line DL may extend in the direction y. In FIG. 7A, the driving voltage line PL extends in the direction x, but in another embodiment, as illustrated in FIG. 6A, the driving voltage line PL may further include the second driving voltage line PLv extended in the direction y and connected to the driving voltage line PL.

The left pixel PXL and the right pixel PXR may share a contact area CNT_VRL where the fifth transistor T5 of the left pixel PXL and the fifth transistor T5 of the right pixel PXR are connected to the reference voltage line VRL.

Referring to FIG. 7B, each of the first to ninth transistors T1 to T9 may include a semiconductor layer and a gate electrode (a gate) overlapping the semiconductor layer. Differences from FIG. 6B are mainly described herein.

The source region S8 of the eighth transistor T8 may be connected to the bias voltage line VBL, which will be disposed over the source region S8 later, through a contact hole in the contact area CNT_VBL. The source region S9 of the ninth transistor T9 may be connected to the driving voltage line PL, which will be disposed over the source region S9 later, through a contact hole in the contact area CNT_PL.

The left pixel PXL and the right pixel PXR may share the semiconductor layer of the eighth transistor T8 and the semiconductor layer of the ninth transistor T9. The left pixel PXL and the right pixel PXR may share the contact area CNT_VBL connecting the eighth transistor T8 to the bias voltage line VBL. The left pixel PXL and the right pixel PXR may share the contact area CNT_PL connecting the ninth transistor T9 to the driving voltage line PL.

The left pixel PXL and the right pixel PXR may each include the fifth transistor T5, and the source region S5 of the fifth transistor T5 of the left pixel PXL and the source region S5 of the fifth transistor T5 of the right pixel PXR may be integrally formed and connected to each other. The left pixel PXL and the right pixel PXR may share the contact area CNT_VRL connecting the fifth transistor T5 to the reference voltage line VRL. The source region S5 of the fifth transistor T5 of the left pixel PXL and the source region S5 of the fifth transistor T5 of the right pixel PXR may be connected to the reference voltage line VRL, which will be disposed over the source region S5 later, through a contact hole in the contact area CNT_VRL.

In an embodiment, the shielding layer SHL covering a semiconductor region (e.g., a semiconductor region between two channel regions) between the gate electrodes G31 and G32 of the third transistor T3 and a semiconductor region (e.g., a semiconductor region between two channel regions) between the gate electrodes G41 and G42 of the fourth transistor T4 may be provided.

FIG. 8 is a diagram schematically illustrating sharing of a transistor between adjacent pixels according to an embodiment. FIG. 8 is a diagram schematically illustrating sharing of a sub-transistor of a fifth transistor, sharing of an eighth transistor, and sharing of a ninth transistor between adjacent pixels.

Referring to FIG. 8, the left pixel PXL and the right pixel PXR adjacent to each other in the direction x (a row direction) may share the eighth transistor T8 and the ninth transistor T9. In some aspects, the left pixel PXL and the right pixel PXR may share the second sub-transistor T5-2 of the fifth transistor T5. Expressed another way, respective fifth transistors T5 of the left pixel PXL and the right pixel PXR may share a second sub-transistor T5-2. Sharing of the eighth transistor T8 and the ninth transistor T9 is the same as described with reference to FIG. 7A, and thus, a detailed description thereof is omitted.

With respect to a boundary between the left pixel PXL and the right pixel PXR, the first to seventh transistors T1 to T7 (e.g., not including the second sub-transistor T5-2) and the first and second capacitors C1 and C2 of the left pixel PXL and the first to seventh transistors T1 to T7 (e.g., not including the second sub-transistor T5-2) and the first and second capacitors C1 and C2 of the right pixel PXR may be arranged symmetric to each other.

The fifth transistor T5 may include the first sub-transistor T5-1 and the second sub-transistor T5-2, and the left pixel PXL and the right pixel PXR may share the second sub-transistor T5-2 of the fifth transistor T5. Expressed another way, the fifth transistor T5 of the left pixel PXL and the fifth transistor T5 of the right pixel PXR may share a second sub-transistor T5-2.

The second sub-transistor T5-2 of the fifth transistor T5 may be arranged between the left pixel PXL and the right pixel PXR, for example, in a boundary area of the left pixel PXL and the right pixel PXR. The second sub-transistor T5-2 may be connected between the first sub-transistor T5-1 of the left pixel PXL and the reference voltage line VRL and may be connected between the first sub-transistor T5-1 of the right pixel PXR and the reference voltage line VRL. The second sub-transistor T5-2 of the fifth transistor T5 may be connected to the reference voltage line VRL in the contact area CNT_VRL. The left pixel PXL and the right pixel PXR may share the second sub-transistor T5-2 and may share the contact area CNT_VRL connecting the second sub-transistor T5-2 to the reference voltage line VRL. The second sub-transistor T5-2 may be closer to the reference voltage line VRL than the first sub-transistor T5-1 of the left pixel PXL. The second sub-transistor T5-2 may be closer to the reference voltage line VRL than the first sub-transistor T5-1 of the right pixel PXR.

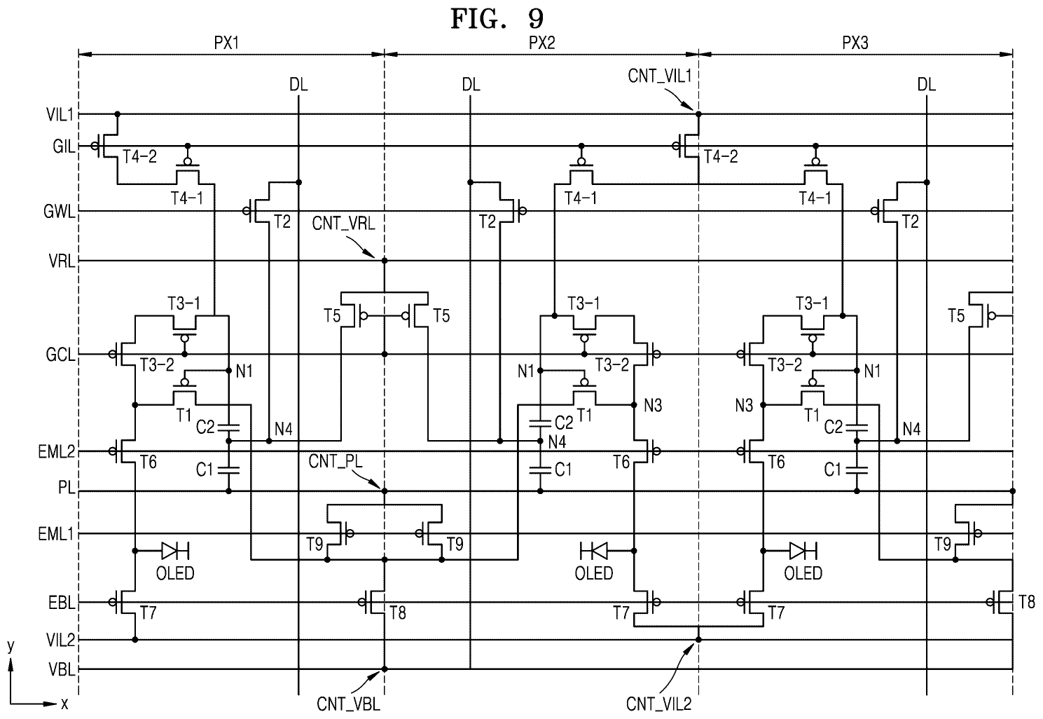

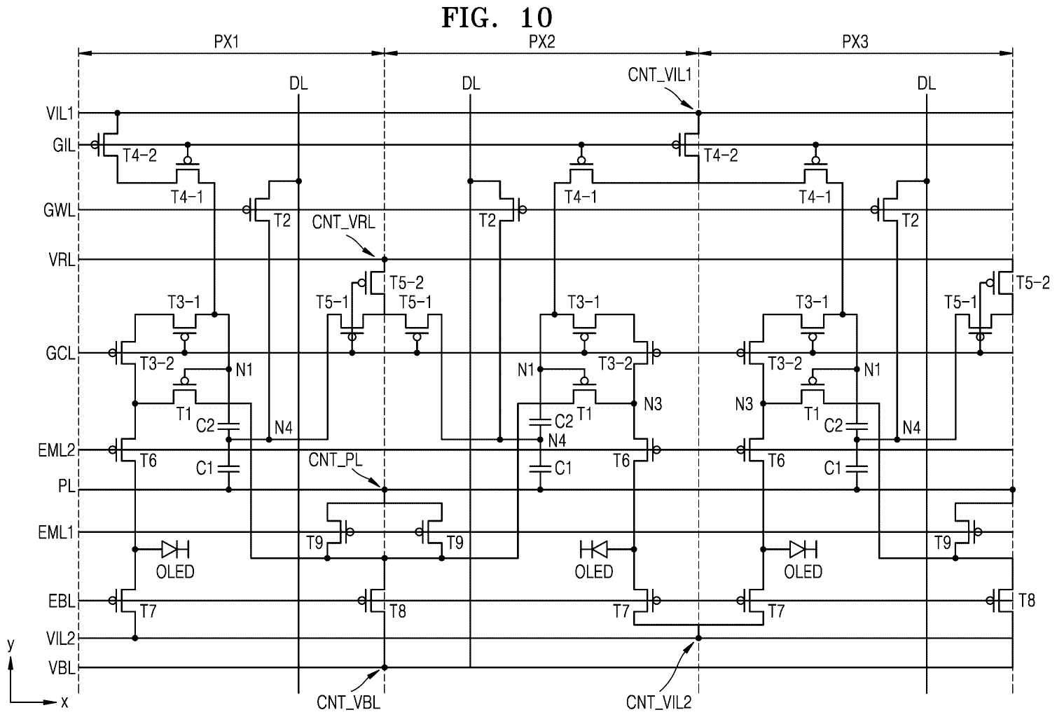

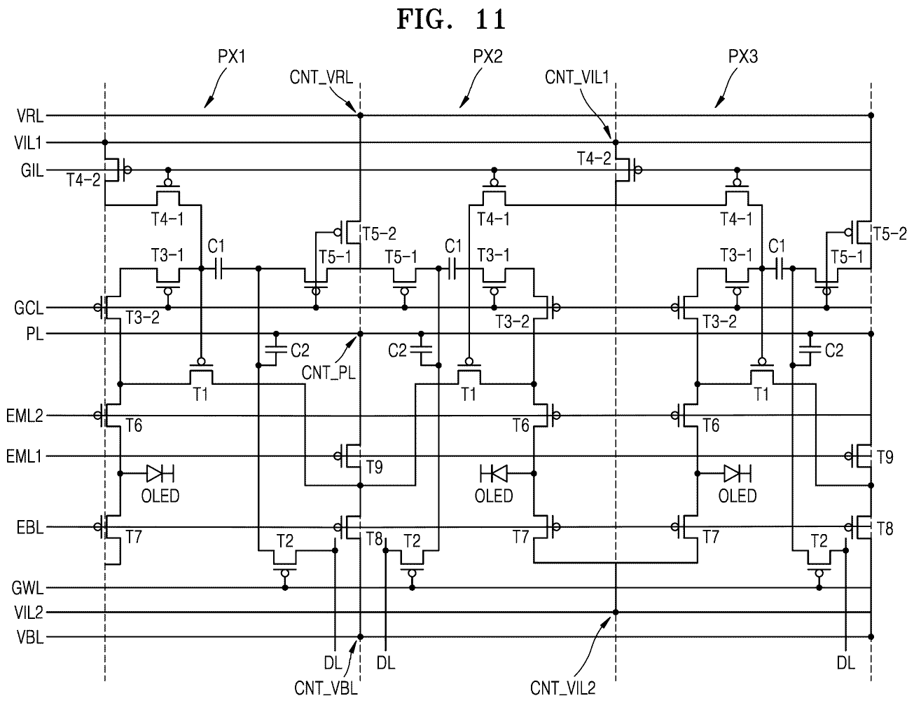

FIGS. 9 to 11 are diagrams schematically illustrating sharing of a transistor between adjacent pixels according to an embodiment. FIGS. 10 and 11 are described focusing on differences from FIG. 9.

Referring to FIG. 9, a first pixel PX1, a second pixel PX2, and a third pixel PX3 adjacent to one another in the direction x may constitute one unit pixel, and the unit pixel may be repeatedly arranged in the direction x in a display area. The first pixel PX1, the second pixel PX2, and the third pixel PX3 constituting the unit pixel may each be a sub-pixel that emits light of a different color. In an embodiment, the first pixel PX1 may be a red pixel, the second pixel PX2 may be a green pixel, and the third pixel PX3 may be a blue pixel.

In an embodiment, as illustrated in FIG. 9, a pair of adjacent pixels, for example, the first pixel PX1 and the second pixel PX2, the second pixel PX2 and the third pixel PX3, and the third pixel PX3 and the first pixel PX1 (the first pixel PX1 arranged right to the third pixel PX3) in the direction x, may share at least one transistor and at least one contact area.

With respect to a boundary between the first pixel PX1 and the second pixel PX2, the first to ninth transistors T1 to T9 and the first and second capacitors C1 and C2 of the first pixel PX1 and the first to ninth transistors T1 to T9 and the first and second capacitors C1 and C2 of the second pixel PX2 may be arranged symmetric to each other. With respect to a boundary between the second pixel PX2 and the third pixel PX3, the first to ninth transistors T1 to T9 and the first and second capacitors C1 and C2 of the second pixel PX2 and the first to ninth transistors T1 to T9 and the first and second capacitors C1 and C2 of the third pixel PX3 may be arranged symmetric to each other. With respect to a boundary between the third pixel PX3 and the first pixel PX1, the first to ninth transistors T1 to T9 and the first and second capacitors C1 and C2 of the third pixel PX3 and the first to ninth transistors T1 to T9 and the first and second capacitors C1 and C2 of the first pixel PX1 may be arranged symmetric to each other.

In an embodiment, as illustrated in FIGS. 9 to 11, the first pixel PX1 and the second pixel PX2 may share the eighth transistor T8 and may share the contact area CNT_VBL connecting the eighth transistor T8 to the bias voltage line VBL.

In an embodiment, as illustrated in FIG. 9, the first pixel PX1 and the second pixel PX2 may share the contact area CNT_VRL connecting the fifth transistor T5 to the reference voltage line VRL.

In an embodiment, as illustrated in FIGS. 10 and 11, the fifth transistor T5 of the first pixel PX1, the second pixel PX2, and the third pixel PX3 may include the first sub-transistor T5-1 and the second sub-transistor T5-2. The first pixel PX1 and the second pixel PX2 may share the second sub-transistor T5-2 of the fifth transistor T5. For example, the fifth transistor T5 of the first pixel PX1 and the fifth transistor T5 of the second pixel PX2 may share a second sub-transistor T5-2. The first pixel PX1 and the second pixel PX2 may share the contact area CNT_VRL connecting the second sub-transistor T5-2 shared by the fifth transistor T5 of the first pixel PX1 and the fifth transistor T5 of the second pixel PX2 to the reference voltage line VRL.

Similarly, for example, the fifth transistor T5 of the third pixel PX3 and the fifth transistor T5 of another first pixel PX1 (not illustrated) neighboring the third pixel PX3 may share a second sub-transistor T5-2. The third pixel PX3 and the other first pixel PX1 may share a contact area CNT_VRL (not illustrated) connecting the second sub-transistor T5-2 shared by the fifth transistor T5 of the third pixel PX3 and the fifth transistor T5 of the other first pixel PX1 to the reference voltage line VRL.

In an embodiment, as illustrated in FIG. 11, the first pixel PX1 and the second pixel PX2 may further share the ninth transistor T9. The first pixel PX1 and the second pixel PX2 may further share the contact area CNT_PL connecting the ninth transistor T9 to the driving voltage line PL.

In an embodiment, as illustrated in FIGS. 9 to 11, the fourth transistor T4 of the first pixel PX1, the second pixel PX2, and the third pixel PX3 may include the first sub-transistor T4-1 and the second sub-transistor T4-2. For example, the fourth transistor T4 of the first pixel PX1 and the fourth transistor T4 of the second pixel PX2 may share a second sub-transistor T4-2 and may share the contact area CNT_VIL1 connecting the second sub-transistor T4-2 to the first initialization voltage line VIL1. The second pixel PX2 and the third pixel PX3 may share the second sub-transistor T4-2 of the fourth transistor T4 and may share the contact area CNT_VIL1 connecting the second sub-transistor T4-2 to the first initialization voltage line VIL1. Expressed another way, the fourth transistor T4 of the second pixel PX2 and the fourth transistor T4 of the third pixel PX3 may share a second sub-transistor T4-2 and may share the contact area CNT_VIL1 connecting the second sub-transistor T4-2 to the first initialization voltage line VIL1.

In an embodiment, as illustrated in FIGS. 9 to 11, the second pixel PX2 and the third pixel PX3 may share the contact area CNT_VIL2 connecting the seventh transistor T7 to the second initialization voltage line VIL2.

In an embodiment, the arrangement of devices in the third pixel PX3 and the first pixel PX1 (the first pixel PX1 arranged right to the third pixel PX3) may be the same as the arrangement of devices in the first pixel PX1 and the second pixel PX2 illustrated in FIGS. 9 to 11.

In an embodiment, the arrangement of devices in the first pixel PX1 and the third pixel PX3 (the third pixel PX3 arranged left to the first pixel PX1) may be the same as the arrangement of devices in the second pixel PX2 and the third pixel PX3 illustrated in FIGS. 9 to 11.

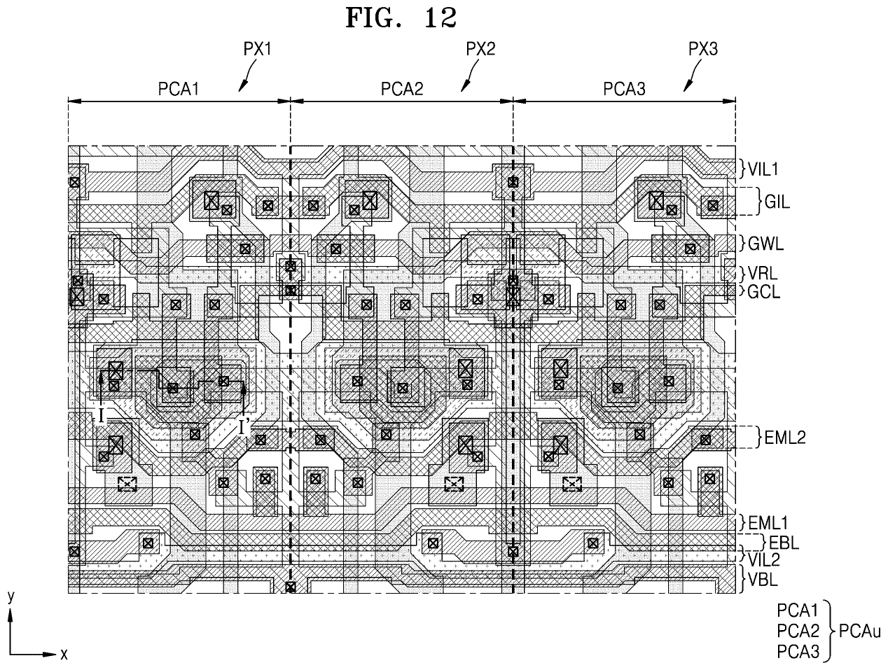

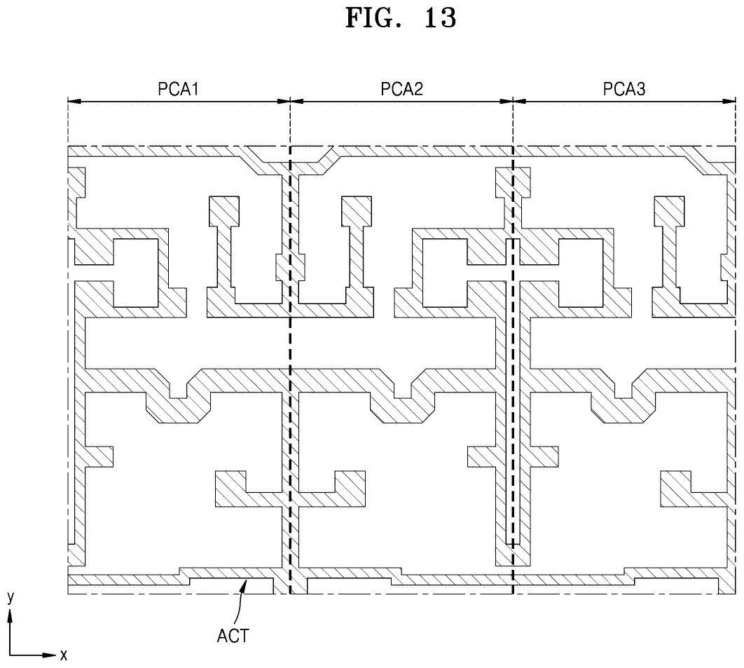

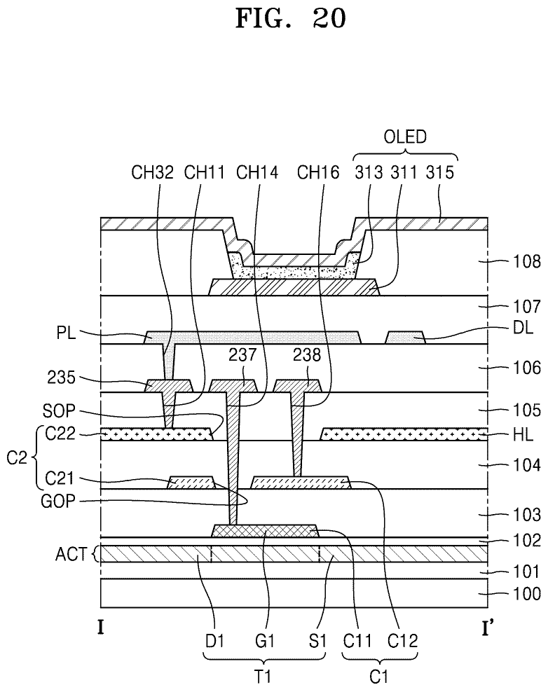

FIG. 12 is a diagram schematically illustrating positions of transistors and capacitors of pixels according to an embodiment. FIGS. 13 to 19 are diagrams schematically illustrating elements of the pixels of FIG. 12 layer by layer. FIG. 20 is a cross-sectional view of a region of FIG. 12, taken along a line I-I′ of FIG. 12.

The display area DA defined on a substrate 100 may include a plurality of circuit areas. The circuit area may be an area where a row (a pixel row) and a column (a pixel column) cross each other and may be an area where a pixel circuit is arranged. In an embodiment, a unit circuit area including two or more circuit areas adjacent to each other in the direction x may be defined, and a unit pixel may be defined by pixels arranged in circuit areas constituting the unit circuit area. For example, a unit circuit area PCAu may include a first circuit area PCA1, a second circuit area PCA2, and a third circuit area PCA3, which are three circuit areas adjacent to one another in the direction x, and a unit pixel may include a first pixel PX1, a second pixel PX2, and a third pixel PX3. The first circuit area PCA1 may be an area where a pixel circuit of the first pixel PX1 is arranged. The second circuit area PCA2 may be an area where a pixel circuit of the second pixel PX2 is arranged. The third circuit area PCA3 may be an area where a pixel circuit of the third pixel PX3 is arranged.

The first pixel PX1, the second pixel PX2, and the third pixel PX3 illustrated in FIG. 12 may correspond to the first pixel PX1, the second pixel PX2, and the third pixel PX3 illustrated in FIG. 10.

The first pixel PX1 and the second pixel PX2 may share the eighth transistor T8 and may share the contact area CNT_VBL connecting the eighth transistor T8 to the bias voltage line VBL. In some aspects, the first pixel PX1 and the second pixel PX2 may share the second sub-transistor T5-2 of the fifth transistor T5 and may share the contact area CNT_VRL connecting the fifth transistor T5 to the reference voltage line VRL. Expressed another way, the fifth transistor T5 of the first pixel PX1 and the fifth transistor T5 of the second pixel PX2 may share a second sub-transistor T5-2 and may share the contact area CNT_VRL connecting the second sub-transistor T5-2 to the reference voltage line VRL.

The second pixel PX2 and the third pixel PX3 may share the second sub-transistor T4-2 of the fourth transistor T4 and may share the contact area CNT_VIL1 connecting the second sub-transistor T4-2 to the first initialization voltage line VIL1. Expressed another way, the fourth transistor T4 of the second pixel PX2 and the fourth transistor T4 of the third pixel PX3 may share a second sub-transistor T4-2 and may share the contact area CNT_VIL1 connecting the second sub-transistor T4-2 to the first initialization voltage line VIL1.

The same devices may be disposed on each layer of the first circuit area PCA1, the second circuit area PCA2, and the third circuit area PCA3. Hereinafter, for convenience of illustration and description, devices of the pixel circuit PC arranged in the first circuit area PCA1 are rendered reference numerals, the first circuit area PCA1 is mainly described, and the same may apply to the same elements of the second circuit area PCA2 and the third circuit area PCA3. Descriptions are given below with reference to FIGS. 13 to 20 together. Hereinafter, a connection electrode may be an electrode that transmits signals by electrically connecting conductive lines and electrodes (conductive patterns) disposed on different layers.

As illustrated in FIGS. 13 and 20, a first insulating layer 101 may be disposed on the substrate 100, and a semiconductor layer ACT may be disposed on the first insulating layer 101.

The semiconductor layer ACT may include a silicon semiconductor. Semiconductor layers ACT of the first circuit area PCA1, the second circuit area PCA2, and the third circuit area PCA3 may be integrally formed and connected to one another. The semiconductor layer ACT may include a source region, a drain region, and a channel region between the source region and the drain region of each of the first to ninth transistors T1 to T9.

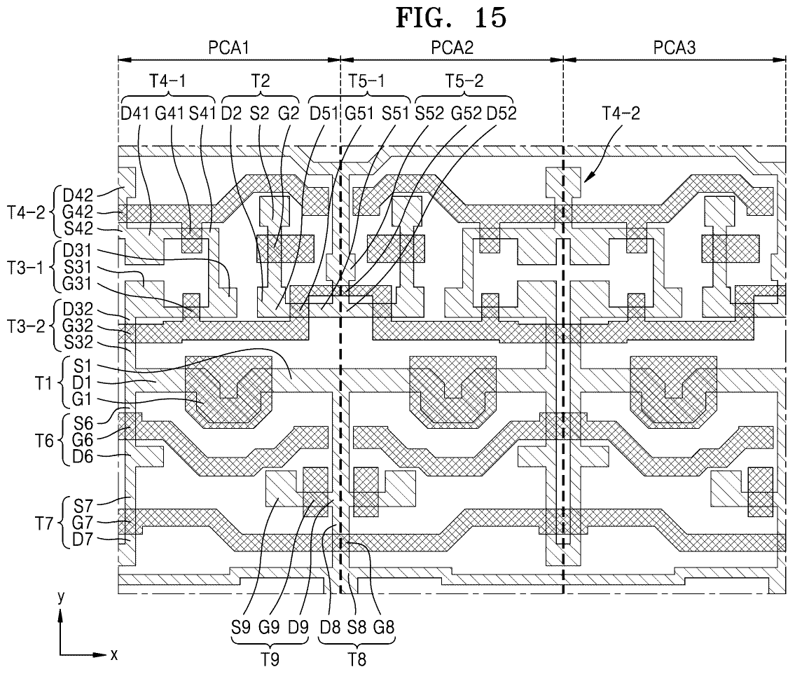

FIG. 15 is a diagram illustrating transistors of the first circuit area PCA1, the second circuit area PCA2, and the third circuit area PCA3. Referring to FIG. 15, the semiconductor layer ACT may include the source region S1 and the drain region D1 of the first transistor T1, the source region S2 and the drain region D2 of the second transistor T2, the source regions S31 and S32 and the drain regions D31 and D32 of the third transistor T3, the source regions S41 and S42 and the drain regions D41 and D42 of the fourth transistor T4, source regions S51 and S52 and drain regions D51 and D52 of the fifth transistor T5, the source region S6 and the drain region D6 of the sixth transistor T6, the source region S7 and the drain region D7 of the seventh transistor T7, the source region S8 and the drain region D8 of the eighth transistor T8, and the source region S9 and the drain region D9 of the ninth transistor T9.

The first pixel PX1 and the second pixel PX2 may share the second sub-transistor T5-2 of the fifth transistor T5 (expressed another way, the fifth transistor T5 of the first pixel PX1 and the fifth transistor T5 of the second pixel PX2 may share a second sub-transistor T5-2), and a semiconductor layer of the second sub-transistor T5-2 may be at a boundary between the first circuit area PCA1 and the second circuit area PCA2.

The first pixel PX1 and the second pixel PX2 may share the eighth transistor T8, and a semiconductor layer of the eighth transistor T8 may be at a boundary between the first circuit area PCA1 and the second circuit area PCA2.

The second pixel PX2 and the third pixel PX3 may share the second sub-transistor T4-2 of the fourth transistor T4 (expressed another way, the fourth transistor T4 of the second pixel PX2 and the fourth transistor T4 of the third pixel PX3 may share a second sub-transistor T4-2), and a semiconductor layer of the second sub-transistor T4-2 may be at a boundary between the second circuit area PCA2 and the third circuit area PCA3.

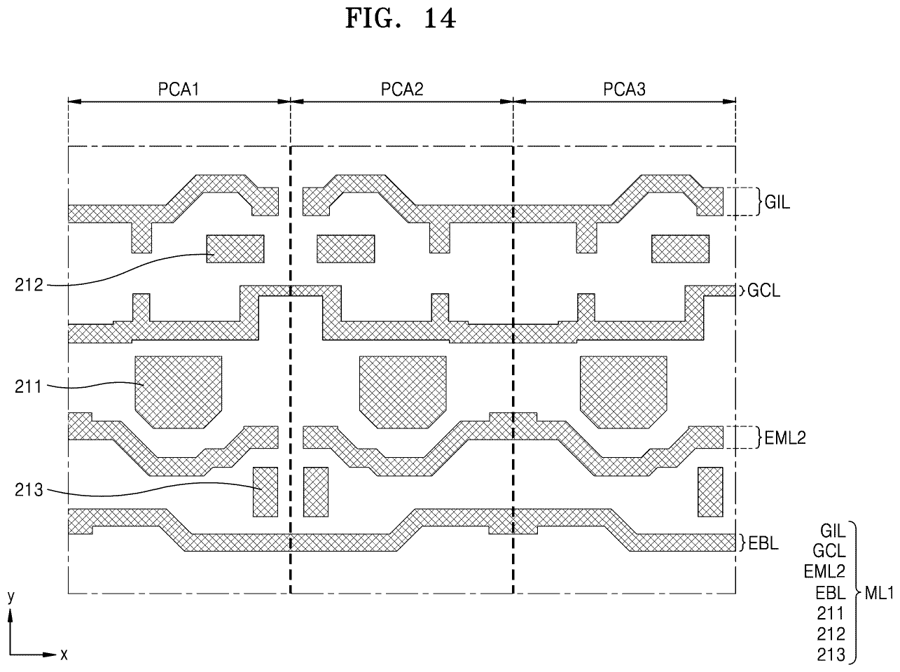

As illustrated in FIGS. 14 and 20, a second insulating layer 102 may be disposed over the first insulating layer 101 and cover the semiconductor layer ACT, and a first conductive layer ML1 may be disposed on the second insulating layer 102. The first conductive layer ML1 may include the second gate line GIL, the third gate line GCL, the fifth gate line EML2, the sixth gate line EBL, a first electrode 211, a second electrode 212, and a third electrode 213.

The first electrode 211, the second electrode 212, and the third electrode 213 may each have an island shape. The first electrode 211, the second electrode 212, and the third electrode 213 may be arranged in each of the first circuit area PCA1, the second circuit area PCA2, and the third circuit area PCA3.

The second gate line GIL may extend in the direction x and may be separated at a boundary between circuit areas of pixels sharing the second sub-transistor T5-2 of the fifth transistor T5, for example, a boundary between the first circuit area PCA1 and the second circuit area PCA2.

The fifth gate line EML2 may extend in the direction x and may be separated at a boundary between circuit areas of pixels sharing the eighth transistor T8, for example, a boundary between the first circuit area PCA1 and the second circuit area PCA2.

The third gate line GCL and the sixth gate line EBL may extend in the direction x and may be arranged across the first circuit area PCA1, the second circuit area PCA2, and the third circuit area PCA3.

As illustrated in FIG. 15, the first conductive layer ML1 may include gate electrodes G1 to G9 of the first to ninth transistors T1 to T9. The gate electrodes G1 to G9 may overlap channel regions of the semiconductor layer ACT.

The first electrode 211 may include the gate electrode G1 of the first transistor T1. The first electrode 211 may include a first electrode C11 (refer to FIG. 20) of the first capacitor C1. The second electrode 212 may include the gate electrode G2 of the second transistor T2. The third electrode 213 may include the gate electrode G9 of the ninth transistor T9. The gate electrodes G41 and G42 of the fourth transistor T4 may be portions of the second gate line GIL. The gate electrodes G51 and G52 of the fifth transistor T5 may be portions of the third gate line GCL. The gate electrode G6 of the sixth transistor T6 may be a portion of the fifth gate line EML2. The gate electrode G7 of the seventh transistor T7 may be a portion of the sixth gate line EBL. The gate electrode G8 of the eighth transistor T8 may be a portion of the sixth gate line EBL.

The gate electrode G52 of the second sub-transistor T5-2 of the fifth transistor T5 shared by the first pixel PX1 and the second pixel PX2 may be at a boundary between the first circuit area PCA1 and the second circuit area PCA2.

The gate electrode G8 of the eighth transistor T8 shared by the first pixel PX1 and the second pixel PX2 may be at a boundary between the first circuit area PCA1 and the second circuit area PCA2.

The gate electrode G42 of the second sub-transistor T4-2 of the fourth transistor T4 shared by the second pixel PX2 and the third pixel PX3 may be at a boundary between the second circuit area PCA2 and the third circuit area PCA3.

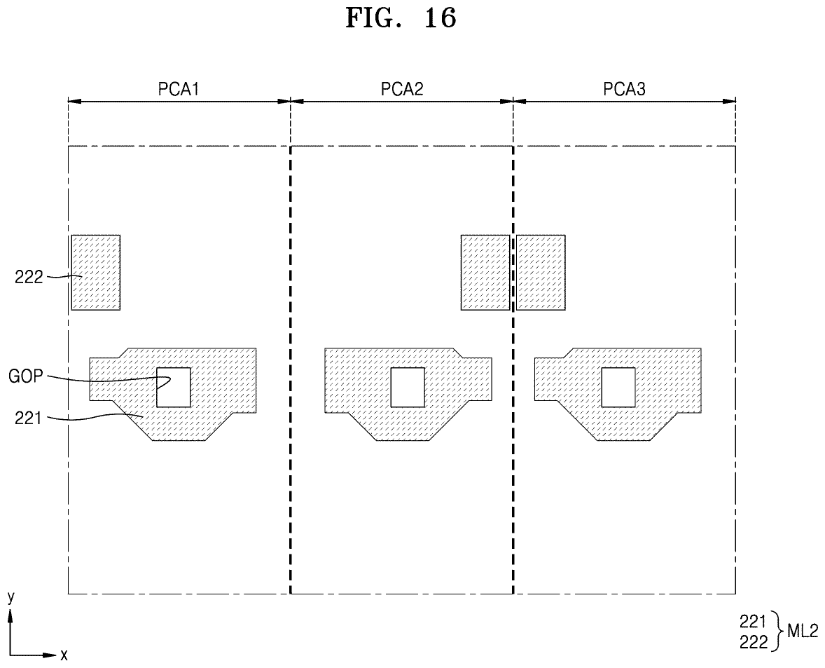

As illustrated in FIGS. 16 and 20, a third insulating layer 103 may be disposed on the second insulating layer 102 and cover the first conductive layer ML1, and a second conductive layer ML2 may be disposed on the third insulating layer 103. The second conductive layer ML2 may include a fourth electrode 221 and a fifth electrode 222.

The fourth electrode 221 and the fifth electrode 222 may each have an island shape. The fourth electrode 221 and the fifth electrode 222 may be arranged in each of the first circuit area PCA1, the second circuit area PCA2, and the third circuit area PCA3.

The fourth electrode 221 may overlap the first electrode 211, and an opening GOP may be defined in the fourth electrode 221. The fourth electrode 221 may include a second electrode C12 (refer to FIG. 20) of the first capacitor C1. The fourth electrode 221 may include a first electrode C21 (refer to FIG. 20) of the second capacitor C2.

The fifth electrode 222 may overlap a semiconductor region (e.g., a semiconductor region between two channel regions) between the gate electrodes G31 and G32 of the third transistor T3 and a semiconductor region (e.g., a semiconductor region between two channel regions) between the gate electrodes G41 and G42 of the fourth transistor T4. The fifth electrode 222 may be a shielding layer of a semiconductor layer.

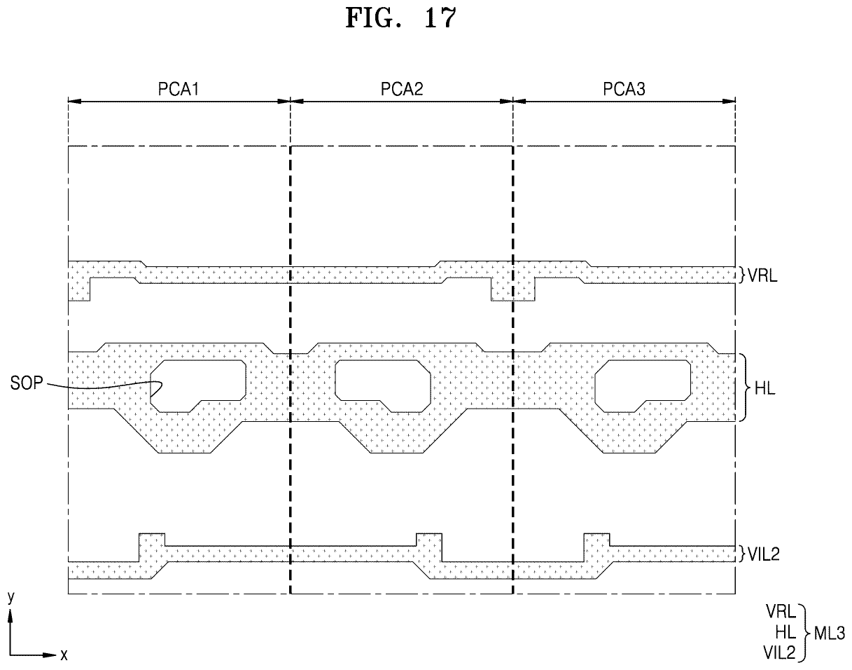

As illustrated in FIGS. 17 and 20, a fourth insulating layer 104 may be disposed on the third insulating layer 103 and cover the second conductive layer ML2, and a third conductive layer ML3 may be disposed on the fourth insulating layer 104. The third conductive layer ML3 may include the reference voltage line VRL, a horizontal voltage line HL, and the second initialization voltage line VIL2.

The reference voltage line VRL, the horizontal voltage line HL, and the second initialization voltage line VIL2 may extend in the direction x and may be arranged across the first circuit area PCA1, the second circuit area PCA2, and the third circuit area PCA3.

The horizontal voltage line HL may overlap the first electrode 211 and the fourth electrode 221. An opening SOP may be defined in the horizontal voltage line HL. The opening SOP may overlap the opening GOP of the fourth electrode 221. A size of the opening SOP may be greater than a size of the opening GOP. The horizontal voltage line HL may include a second electrode C22 (refer to FIG. 20) of the second capacitor C2.

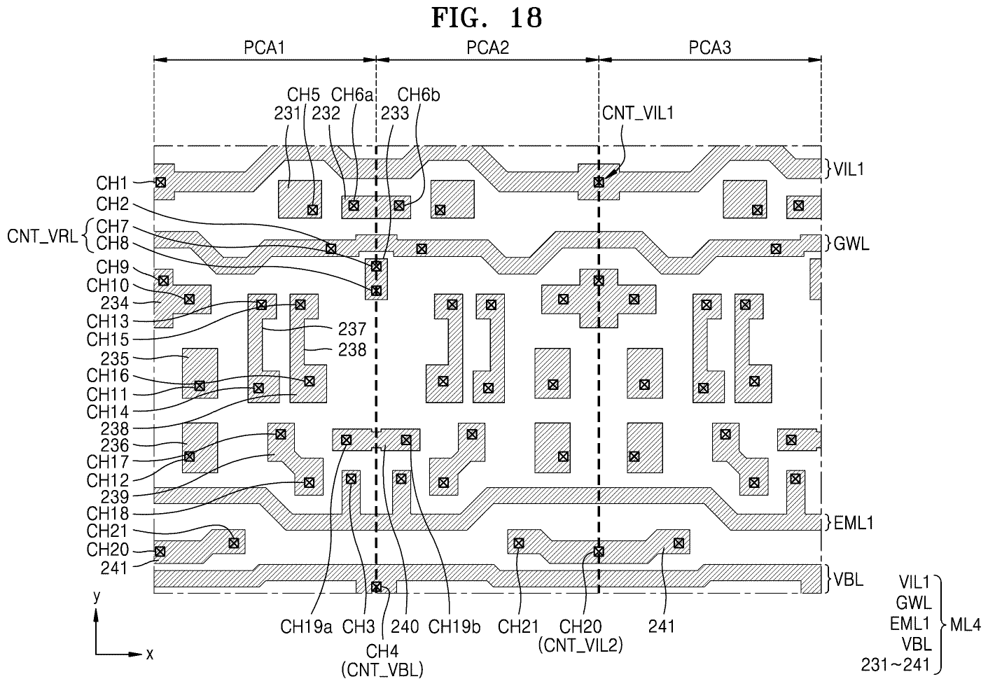

As illustrated in FIGS. 18 and 20, a fifth insulating layer 105 may be disposed on the fourth insulating layer 104 and cover the third conductive layer ML3, and a fourth conductive layer ML4 may be disposed on the fifth insulating layer 105. The fourth conductive layer ML4 may include the first initialization voltage line VIL1, the first gate line GWL, the fourth gate line EML1, the bias voltage line VBL, and connection electrodes 231, 232, 233, 234, 235, 236, 237, 238, 239, 240, and 241.

The first initialization voltage line VIL1, the first gate line GWL, the fourth gate line EML1, and the bias voltage line VBL may extend in the direction x and may be arranged across the first circuit area PCA1, the second circuit area PCA2, and the third circuit area PCA3.

The first initialization voltage line VIL1 may be connected to the drain region D42 of the second sub-transistor T4-2 of the fourth transistor T4 through a contact hole CH1 penetrating the second insulating layer 102, the third insulating layer 103, the fourth insulating layer 104, and the fifth insulating layer 105. The contact hole CH1 may be positioned in the contact area CNT_VIL1 where the drain region D42 of the second sub-transistor T4-2 of the fourth transistor T4 is connected to the first initialization voltage line VIL1.

The first gate line GWL may be connected to the second electrode 212, which is the gate electrode G2 of the second transistor T2, through a contact hole CH2 penetrating the third insulating layer 103, the fourth insulating layer 104, and the fifth insulating layer 105.

The fourth gate line EML1 may be connected to the gate electrode G9 of the ninth transistor T9 through a contact hole CH3 penetrating the third insulating layer 103, the fourth insulating layer 104, and the fifth insulating layer 105.

The bias voltage line VBL may be connected to the source region S8 of the eighth transistor T8 through a contact hole CH4 penetrating the second insulating layer 102, the third insulating layer 103, the fourth insulating layer 104, and the fifth insulating layer 105. The contact hole CH4 may be positioned in the contact area CNT_VBL where the source region S8 of the eighth transistor T8 is connected to the bias voltage line VBL.

The connection electrode 231 may be connected to the source region S2 of the second transistor T2 through a contact hole CH5 penetrating the second insulating layer 102, the third insulating layer 103, the fourth insulating layer 104, and the fifth insulating layer 105.

The connection electrode 232 may be arranged between two adjacent circuit areas and may be connected to the second gate line GIL. For example, the connection electrode 232 may be at a boundary between the first circuit area PCA1 and the second circuit area PCA2 and may be connected to the second gate line GIL through contact holes CH6a and CH6b penetrating the third insulating layer 103, the fourth insulating layer 104, and the fifth insulating layer 105. Accordingly, second gate lines GIL separated at the boundary between the first circuit area PCA1 and the second circuit area PCA2 may be connected.

The connection electrode 233 may be connected to the source region S5 of the second sub-transistor T5-2 of the fifth transistor T5 through a contact hole CH7 penetrating the second insulating layer 102, the third insulating layer 103, the fourth insulating layer 104, and the fifth insulating layer 105. The connection electrode 233 may be connected to the reference voltage line VRL through a contact hole CH8 penetrating the fifth insulating layer 105. An area including the contact hole CH7 and the contact hole CH8 may be the contact area CNT_VRL where the source region S5 of the second sub-transistor T5-2 is connected to the reference voltage line VRL.

The connection electrode 234 may be connected to the reference voltage line VRL through a contact hole CH9 penetrating the fifth insulating layer 105. The connection electrode 234 may be connected to the fifth electrode 222 through a contact hole CH10 penetrating the fourth insulating layer 104 and the fifth insulating layer 105. Accordingly, the fifth electrode 222 may receive the reference voltage VREF.

The connection electrode 235 may be connected to the horizontal voltage line HL through a contact hole CH11 penetrating the fifth insulating layer 105.

The connection electrode 236 may be connected to the drain region D6 of the sixth transistor T6 and the source region S7 of the seventh transistor T7 through a contact hole CH12 penetrating the second insulating layer 102, the third insulating layer 103, the fourth insulating layer 104, and the fifth insulating layer 105.

The connection electrode 237 may be connected to the drain region D31 of the first sub-transistor T3-1 of the third transistor T3 and the source region S41 of the first sub-transistor T4-1 of the fourth transistor T4 through a contact hole CH13 penetrating the second insulating layer 102, the third insulating layer 103, the fourth insulating layer 104, and the fifth insulating layer 105. The connection electrode 237 may be connected to the first electrode 211, which is the gate electrode G1 of the first transistor T1, through a contact hole CH14 penetrating the third insulating layer 103, the fourth insulating layer 104, and the fifth insulating layer 105. The contact hole CH14 may be in the opening GOP of the fourth electrode 221 and the opening SOP of the horizontal voltage line HL.

The connection electrode 238 may be connected to the drain region D2 of the second transistor T2 and the drain region D51 of the first sub-transistor T5-1 of the fifth transistor T5 through a contact hole CH15 penetrating the second insulating layer 102, the third insulating layer 103, the fourth insulating layer 104, and the fifth insulating layer 105. The connection electrode 238 may be connected to the fourth electrode 221 through a contact hole CH16 penetrating the fourth insulating layer 104 and the fifth insulating layer 105. The contact hole CH16 may be in the opening SOP of the horizontal voltage line HL.

The connection electrode 239 may be connected to the horizontal voltage line HL through a contact hole CH17 penetrating the fifth insulating layer 105. The connection electrode 239 may be connected to the source region S9 of the ninth transistor T9 through a contact hole CH18 penetrating the second insulating layer 102, the third insulating layer 103, the fourth insulating layer 104, and the fifth insulating layer 105.

The connection electrode 240 may be arranged between two adjacent circuit areas and may be connected to the fifth gate line EML2. For example, the connection electrode 240 may be at a boundary between the first circuit area PCA1 and the second circuit area PCA2 and may be connected to the fifth gate line EML2 through contact holes CH19a and CH19b penetrating the third insulating layer 103, the fourth insulating layer 104, and the fifth insulating layer 105. Accordingly, fifth gate lines EML2 separated at the boundary between the first circuit area PCA1 and the second circuit area PCA2 may be connected.

The connection electrode 241 may be arranged between two adjacent circuit areas. The connection electrode 241 may be connected to the drain region D7 of the seventh transistor T7 through a contact hole CH20 penetrating the second insulating layer 102, the third insulating layer 103, the fourth insulating layer 104, and the fifth insulating layer 105. The connection electrode 241 may be connected to the second initialization voltage line VIL2 through a contact hole CH21 penetrating the fifth insulating layer 105. The contact hole CH20 may be positioned in the contact area CNT_VIL2 where the drain region D7 of the seventh transistor T7 is connected to the second initialization voltage line VIL2.

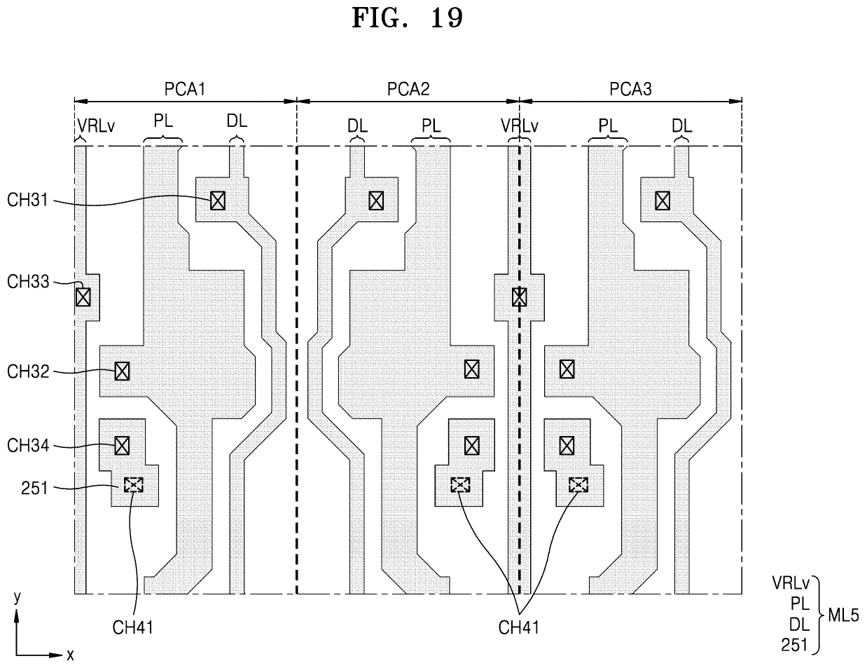

As illustrated in FIGS. 19 and 20, a sixth insulating layer 106 may be disposed on the fifth insulating layer 105 and cover the fourth conductive layer ML4, and a fifth conductive layer ML5 may be disposed on the sixth insulating layer 106. The fifth conductive layer ML5 may include the data line DL, the driving voltage line PL, a vertical reference voltage line VRLv, and a connection electrode 251.

The data line DL may be arranged in each circuit area while extending in the direction y. The data line DL may be connected to the connection electrode 231 through a contact hole CH31 penetrating the sixth insulating layer 106. Because the connection electrode 231 is connected to the source region S2 of the second transistor T2, the data line DL may be connected to the source region S2 of the second transistor T2.

The driving voltage line PL may be connected to the connection electrode 235 through a contact hole CH32 penetrating the sixth insulating layer 106. Because the connection electrode 235 is connected to the horizontal voltage line HL, the horizontal voltage line HL may receive the driving voltage ELVDD. In an embodiment, the horizontal voltage line HL may be referred to as a first driving voltage line in the direction x, and the driving voltage line PL may be referred to as a second driving voltage line in the direction y. A conductive line configured to supply the driving voltage ELVDD may be understood as having a grid structure due to the horizontal voltage line HL and the driving voltage line PL. The driving voltage line PL illustrated in FIG. 9 may correspond to the horizontal voltage line HL illustrated in FIG. 17.

The vertical reference voltage line VRLv may be connected to the connection electrode 234 connected to the reference voltage line VRL through a contact hole CH33 penetrating the sixth insulating layer 106. The reference voltage line VRL may be referred to as a horizontal reference voltage line, and a conductive line configured to supply the reference voltage VREF may be understood as having a grid structure due to the reference voltage line VRL and the vertical reference voltage line VRLv.

The connection electrode 251 may be connected to the connection electrode 236 through a contact hole CH34 penetrating the sixth insulating layer 106.

As illustrated in FIG. 20, a seventh insulating layer 107 may be disposed on the sixth insulating layer 106 and cover the fifth conductive layer ML5, and the organic light-emitting diode OLED may be disposed on the seventh insulating layer 107.

The organic light-emitting diode OLED may include a pixel electrode 311, an opposite electrode 315, and an intermediate layer between the pixel electrode 311 and the opposite electrode 315. An eighth insulating layer 108 may be arranged on the seventh insulating layer 107. The eighth insulating layer 108 may cover a part of the pixel electrode 311.

The pixel electrode 311 may be connected to the connection electrode 251 connected to the connection electrode 236 through a contact hole CH41 (refer to FIG. 19) of the seventh insulating layer 107. Because the connection electrode 236 is connected to the drain region D6 of the sixth transistor T6, the pixel electrode 311 may be connected to the drain region D6 of the sixth transistor T6.

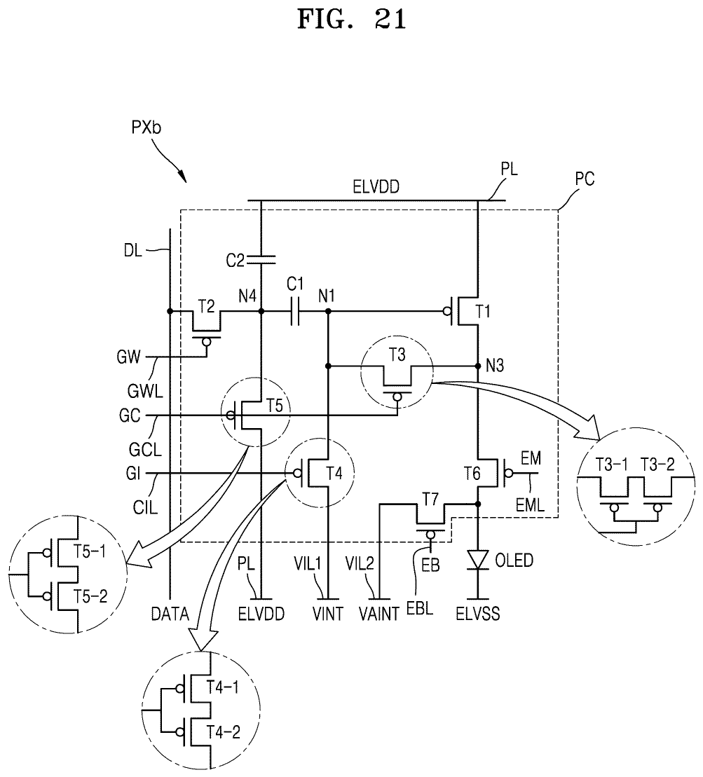

FIGS. 21 to 23 are schematic diagrams of a pixel according to an embodiment. Pixels PXb described with reference to FIGS. 21 to 23 may include aspects of pixels PXa described with reference to FIGS. 3 to 5. Differences from the pixels PXa illustrated in FIGS. 3 to 5 are mainly described herein.

A pixel PXb illustrated in FIG. 21 is different from the pixel PXa illustrated in FIG. 3 in that the eighth transistor T8 and the ninth transistor T9 are omitted and the fifth transistor T5 is connected to the driving voltage line PL.

The fifth transistor T5 may be connected between the fourth node N4 and the driving voltage line PL. The fifth transistor T5 may include a gate connected to the third gate line GCL, a first terminal connected to the driving voltage line PL, and a second terminal connected to the fourth node N4. The fifth transistor T5 may be turned on according to the third gate signal GC received through the third gate line GCL to transmit the driving voltage ELVDD to the fourth node N4.

In an embodiment, as illustrated in FIG. 21, the fifth transistor T5 of the pixel PXb may be a dual gate transistor in which a pair of sub-transistors (e.g., the first sub-transistor T5-1 and the second sub-transistor T5-2) are connected in series.

In an embodiment, as illustrated in FIG. 21, the third transistor T3 of the pixel PXb may be a dual gate transistor in which a pair of sub-transistors (e.g., the first sub-transistor T3-1 and the second sub-transistor T3-2) are connected in series.

As illustrated in FIG. 21, the fourth transistor T4 of the pixel PXb may be a dual gate transistor in which a pair of sub-transistors (e.g., the first sub-transistor T4-1 and the second sub-transistor T4-2) are connected in series.

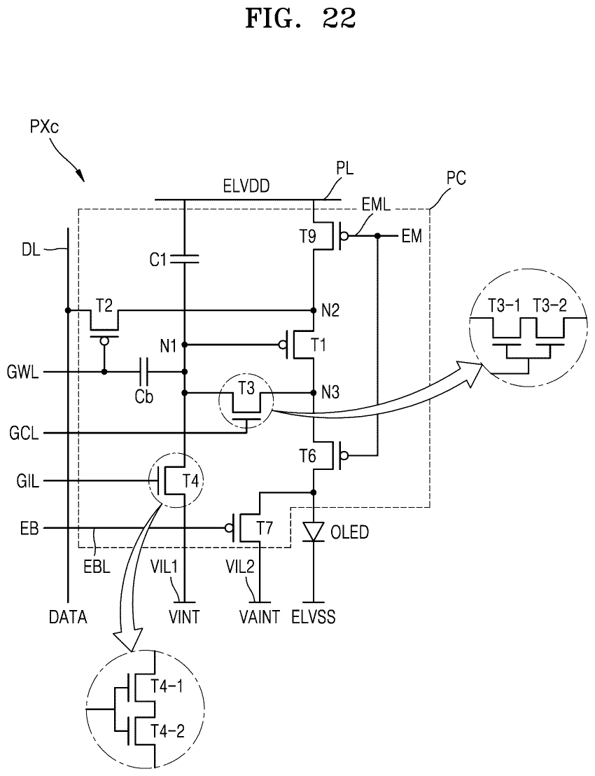

A pixel PXc illustrated in FIG. 22 is different from the pixel PXa illustrated in FIG. 3 in that the second capacitor C2, the fifth transistor T5, and the eighth transistor T8 are omitted and in terms of connection relationships between some of the other transistors and the first capacitor C1.

The second transistor T2 may be connected between the data line DL and the second node N2. The second transistor T2 may include a gate connected to the first gate line GWL, a first terminal connected to the data line DL, and a second terminal connected to the second node N2. The second transistor T2 may be turned on according to the first gate signal GW received through the first gate line GWL to perform a switching operation for transmitting the data signal DATA transmitted to the data line DL to the second node N2.

The first capacitor C1 may be connected between the driving voltage line PL and the first node N1.

In an embodiment, the pixel PXc may further include a boost capacitor Cb, and the boost capacitor Cb may be connected between the gate of the second transistor T2 and the first node N1.

A gate of the ninth transistor T9 and a gate of the sixth transistor T6 may be connected to a gate line EML configured to receive a gate signal EM. In an embodiment, the gate line EML may be the fourth gate line EML1 (FIGS. 3 to 5) configured to receive the fourth gate signal EM1 (FIGS. 3 to 5). In an embodiment, the gate line EML may be the fifth gate line EML2 (FIGS. 3 to 5) configured to receive the fifth gate signal EM2 (FIGS. 3 to 5). In the pixel PXc illustrated in FIG. 22, the gate of the ninth transistor T9 and the gate of the sixth transistor T6 may be connected to the same gate line to receive the same gate signal, thereby reducing the number of gate lines and gate signals compared to the pixel PXa illustrated in FIG. 3.

In an embodiment, as illustrated in FIG. 22, the third transistor T3 of the pixel PXc may be a dual gate transistor in which a pair of sub-transistors (e.g., the first sub-transistor T3-1 and the second sub-transistor T3-2) are connected in series.

In an embodiment, as illustrated in FIG. 22, the fourth transistor T4 of the pixel PXc may be a dual gate transistor in which a pair of sub-transistors (e.g., the first sub-transistor T4-1 and the second sub-transistor T4-2) are connected in series.

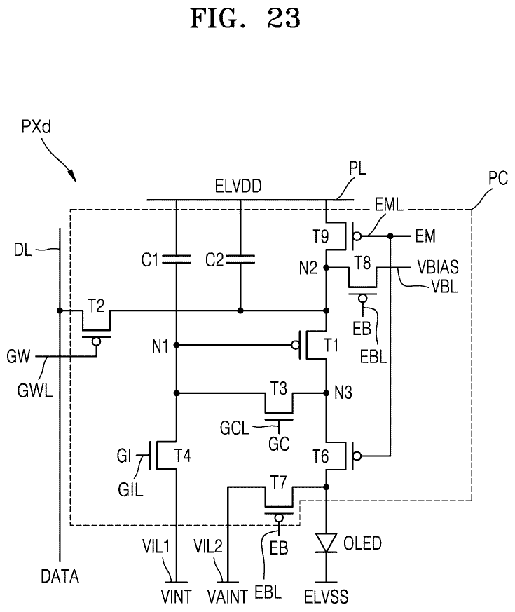

A pixel PXd illustrated in FIG. 23 is different from the pixel PXa illustrated in FIG. 3 in that the fifth transistor T5 is omitted and in terms of connection relationships between some of the other transistors and the first capacitor C1 and the second capacitor C2.

The second transistor T2 may be connected between the data line DL and the second node N2. The second transistor T2 may include a gate connected to the first gate line GWL, a first terminal connected to the data line DL, and a second terminal connected to the second node N2. The second transistor T2 may be turned on according to the first gate signal GW received through the first gate line GWL in association with transmitting the data signal DATA transmitted to the data line DL to the second node N2.

The first capacitor C1 may be connected between the driving voltage line PL and the first node N1.

The second capacitor C2 may be connected between the driving voltage line PL and the second node N2.

A gate of the ninth transistor T9 and a gate of the sixth transistor T6 may be connected to the gate line EML configured to receive the gate signal EM. In an embodiment, the gate line EML may be the fourth gate line EML1 (FIGS. 3 to 5) configured to receive the fourth gate signal EM1 (FIGS. 3 to 5). In an embodiment, the gate line EML may be the fifth gate line EML2 (FIGS. 3 to 5) configured to receive the fifth gate signal EM2 (FIGS. 3 to 5).

In an embodiment, as illustrated in FIGS. 4 and 5, the third transistor T3 of the pixel PXd in FIG. 23 may be a dual gate transistor in which a pair of sub-transistors (e.g., the first sub-transistor T3-1 and the second sub-transistor T3-2) are connected in series.

In an embodiment, as illustrated in FIGS. 4 and 5, the fourth transistor T4 of the pixel PXd in FIG. 23 may be a dual gate transistor in which a pair of sub-transistors (e.g., the first sub-transistor T4-1 and the second sub-transistor T4-2) are connected in series.

In the pixels PXb, PXc, and PXd illustrated in FIGS. 21 to 23, as illustrated in FIGS. 6A to 11, neighboring pixels may share one of the sub-transistors of at least one of the fourth transistor T4 and the fifth transistor T5. For example, two neighboring pixels may share the second sub-transistor T4-2 of the fourth transistor T4 and may share a contact area connecting the second sub-transistor T4-2 to the first initialization voltage line VIL1. Two neighboring pixels may share the second sub-transistor T5-2 of the fifth transistor T5 and may share a contact area connecting the second sub-transistor T5-2 to the driving voltage line PL. Expressed another way, respective fifth transistors T5 of neighboring pixels may share a second sub-transistor T5-2 and may share the contact area connecting the second sub-transistor T5-2 to the driving voltage line PL.

In the pixels PXb, PXc, and PXd illustrated in FIGS. 21 to 23, as illustrated in FIGS. 6A to 11, neighboring pixels may share at least one transistor (e.g., at least one of the seventh transistor T7, the eighth transistor T8, and the ninth transistor T9) constituting a pixel circuit. For example, two neighboring pixels may share the seventh transistor T7 and may share a contact area connecting the seventh transistor T7 to the second initialization voltage line VIL2. Two neighboring pixels may share the eighth transistor T8 and may share a contact area connecting the eighth transistor T8 to the bias voltage line VBL. Two neighboring pixels may share the ninth transistor T9 and may share a contact area connecting the ninth transistor T9 to the driving voltage line PL.

In the pixels PXb, PXc, and PXd illustrated in FIGS. 21 to 23, as illustrated in FIGS. 6A to 11, neighboring pixels may share a contact area connecting at least one transistor constituting a pixel circuit to a voltage line. For example, two neighboring pixels may each include the seventh transistor T7 and may share a contact area connecting the seventh transistor T7 to the second initialization voltage line VIL2. Two neighboring pixels may each include the eighth transistor T8 and may share a contact area connecting the eighth transistor T8 to the bias voltage line VBL. Two neighboring pixels may each include the ninth transistor T9 and may share a contact area connecting the ninth transistor T9 to the driving voltage line PL.

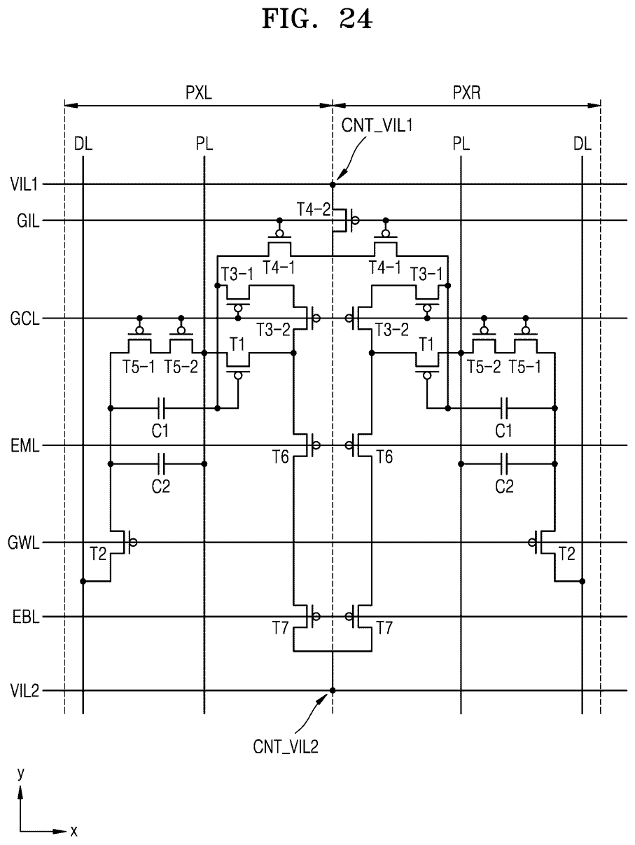

FIG. 24 is a diagram schematically illustrating sharing of a transistor between adjacent pixels according to an embodiment. FIG. 24 is a diagram schematically illustrating sharing of a fourth transistor between adjacent pixels. FIG. 24 is a diagram illustrating the pixel illustrated in FIG. 21.

Referring to FIG. 24, the left pixel PXL and the right pixel PXR adjacent to each other in the direction x (a row direction) may share the second sub-transistor T4-2 of the fourth transistor T4. Expressed another way, respective fourth transistors T4 of the left pixel PXL and the right pixel PXR may share a second sub-transistor T4-2.

The second sub-transistor T4-2 of the fourth transistor T4 may be arranged in a boundary area of the left pixel PXL and the right pixel PXR. With respect to a boundary between the left pixel PXL and the right pixel PXR, the first to seventh transistors T1 to T7 and the first and second capacitors C1 and C2 of the left pixel PXL and the first to seventh transistors T1 to T7 and the first and second capacitors C1 and C2 of the right pixel PXR may be arranged symmetric to each other.

The second sub-transistor T4-2 of the fourth transistor T4 may be connected to the first initialization voltage line VIL1 in the contact area CNT_VIL1. The left pixel PXL and the right pixel PXR may share the second sub-transistor T4-2 and may share the contact area CNT_VIL1 connecting the second sub-transistor T4-2 to the first initialization voltage line VIL1.

The left pixel PXL and the right pixel PXR may each include the seventh transistor T7, and the seventh transistor T7 of the left pixel PXL and the seventh transistor T7 of the right pixel PXR may be connected to the second initialization voltage line VIL2 in the contact area CNT_VIL2. The left pixel PXL and the right pixel PXR may share the contact area CNT_VIL2 where the seventh transistor T7 of the left pixel PXL and the seventh transistor T7 of the right pixel PXR are connected to the second initialization voltage line VIL2.

According to one or more of the above embodiments, pixel circuits may be symmetrically arranged with respect to a boundary between neighboring pixels, and pixels having pixel circuits which are symmetric to each other may share at least one transistor and at least one contact area. Accordingly, embodiments of the present disclosure support implementing a high-resolution display apparatus by increasing integration efficiency of a pixel circuit and increasing pixel density.

According to one or more of the above embodiments, a high-resolution display apparatus may be provided. However, one or more embodiments are not limited by such an effect.

It should be understood that embodiments described herein should be considered in a descriptive sense and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

1. A display apparatus comprising:
a plurality of pixels,
wherein each of the plurality of pixels comprises:
a first transistor;
a second transistor connected to a data line;
a third transistor connected to a gate of the first transistor and a second terminal of the first transistor;
a fourth transistor connected to the gate of the first transistor and a first initialization voltage line;
a fifth transistor connected to the second transistor and a reference voltage line, wherein the fifth transistor comprises a first sub-transistor; and
a capacitor connected to the gate of the first transistor and the second transistor,
wherein the plurality of pixels comprise a first pixel and a second pixel adjacent to the first pixel,
wherein the fifth transistor comprised in the first pixel and the fifth transistor comprised in the second pixel further comprise a second sub-transistor shared by the first pixel and the second pixel, and
wherein the second sub-transistor shared by the first pixel and the second pixel:
is connected in series with the first sub-transistor of the fifth transistor of the first pixel and is closer to the reference voltage line than the first sub-transistor of the fifth transistor of the first pixel; and
is connected in series with the first sub-transistor of the fifth transistor of the second pixel and is closer to the reference voltage line than the first sub-transistor of the fifth transistor of the second pixel.

2. The display apparatus of claim 1, wherein the first pixel and the second pixel share a contact area where the second sub-transistor is connected to the reference voltage line.

3. The display apparatus of claim 1, wherein the second sub-transistor is arranged at a boundary between the first pixel and the second pixel, and
wherein an arrangement of transistors of the first pixel, other than the second sub-transistor, and an arrangement of transistors of the second pixel, other than the second sub-transistor, are symmetric to each other with respect to the boundary between the first pixel and the second pixel.

4. The display apparatus of claim 1, wherein the first pixel and the second pixel share a sixth transistor connected to a driving voltage line, and
wherein the sixth transistor shared by the first pixel and the second pixel is connected to a first terminal of the first transistor of the first pixel and a first terminal of the first transistor of the second pixel.

5. The display apparatus of claim 4, wherein the sixth transistor shared by the first pixel and the second pixel is arranged at a boundary between the first pixel and the second pixel, and
wherein an arrangement of transistors of the first pixel, other than the sixth transistor, and an arrangement of transistors of the second pixel, other than the sixth transistor, are symmetric to each other with respect to the boundary between the first pixel and the second pixel.

6. The display apparatus of claim 1, wherein the first pixel and the second pixel share a seventh transistor connected to a bias voltage line, and
wherein the seventh transistor shared by the first pixel and the second pixel is connected to a first terminal of the first transistor of the first pixel and a first terminal of the first transistor of the second pixel.

7. The display apparatus of claim 6, wherein the seventh transistor shared by the first pixel and the second pixel is arranged at a boundary between the first pixel and the second pixel, and
wherein an arrangement of transistors of the first pixel, other than the seventh transistor, and an arrangement of transistors of the second pixel, other than the seventh transistor, are symmetric to each other with respect to the boundary between the first pixel and the second pixel.

8. The display apparatus of claim 1, wherein the fourth transistor comprises a first sub-transistor,
wherein the plurality of pixels further comprise a third pixel adjacent to the second pixel,
wherein the fourth transistor comprised in the second pixel and the fourth transistor comprised in the third pixel further comprise a second sub-transistor shared by the second pixel and the third pixel, and
wherein the second sub-transistor shared by the second pixel and the third pixel:
is connected in series with the first sub-transistor of the fourth transistor of the second pixel and is closer to the first initialization voltage line than the first sub-transistor of the fourth transistor of the second pixel; and
is connected in series with the first sub-transistor of the fourth transistor of the third pixel and is closer to the first initialization voltage line than the first sub-transistor of the fourth transistor of the third pixel.

9. The display apparatus of claim 8, wherein the second sub-transistor of the fourth transistor is arranged at a boundary between the second pixel and the third pixel, and
wherein an arrangement of transistors of the second pixel, other than the second sub-transistor of the fourth transistor, and an arrangement of transistors of the third pixel, other than the second sub-transistor of the fourth transistor, are symmetric to each other with respect to the boundary between the second pixel and the third pixel.

10. The display apparatus of claim 1, wherein each of the plurality of pixels further comprises:
an eighth transistor connected to the second terminal of the first transistor and a light-emitting element; and
a ninth transistor connected to the light-emitting element and a second initialization voltage line,
wherein the plurality of pixels further comprise a third pixel adjacent to the second pixel, and
wherein the second pixel and the third pixel share a contact area where the ninth transistor of the second pixel and the ninth transistor of the third pixel are connected to the second initialization voltage line.

11. A display apparatus comprising:
a plurality of pixels,
wherein each of the plurality of pixels comprises:
a first transistor;
a second transistor connected to a data line;
a third transistor connected to a gate of the first transistor and a second terminal of the first transistor;
a fourth transistor connected to the gate of the first transistor and a first initialization voltage line;
a fifth transistor connected to the second transistor and a reference voltage line; and
a capacitor connected to the gate of the first transistor and the second transistor,
wherein the plurality of pixels comprise a first pixel and a second pixel adjacent to the first pixel, wherein the first pixel and the second pixel share:
a sixth transistor connected to a bias voltage line, and
wherein the sixth transistor shared by the first pixel and the second pixel is connected to a first terminal of the first transistor of the first pixel and a first terminal of the first transistor of the second pixel.

12. The display apparatus of claim 11, wherein the sixth transistor shared by the first pixel and the second pixel is arranged at a boundary between the first pixel and the second pixel, and
wherein an arrangement of transistors of the first pixel, other than the sixth transistor, and an arrangement of transistors of the second pixel, other than the sixth transistor, are symmetric to each other with respect to the boundary between the first pixel and the second pixel.

13. The display apparatus of claim 11, wherein the first pixel and the second pixel share a seventh transistor connected to a driving voltage line, and
wherein the seventh transistor shared by the first pixel and the second pixel is connected to the first terminal of the first transistor of the first pixel and the first terminal of the first transistor of the second pixel.

14. The display apparatus of claim 13, wherein the seventh transistor shared by the first pixel and the second pixel is arranged at a boundary between the first pixel and the second pixel, and
wherein an arrangement of transistors of the first pixel, other than the seventh transistor, and an arrangement of transistors of the second pixel, other than the seventh transistor, are symmetric to each other with respect to the boundary between the first pixel and the second pixel.

15. The display apparatus of claim 11, wherein the first pixel and the second pixel share a contact area where the fifth transistor of the first pixel and the fifth transistor of the second pixel are connected to the reference voltage line.

16. The display apparatus of claim 11, wherein:
the fifth transistor comprised in the first pixel and the fifth transistor comprised in the second pixel each comprise a first sub-transistor, and
the fifth transistor comprised in the first pixel and the fifth transistor comprised in the second pixel further comprise a second sub-transistor shared by the first pixel and the second pixel, and
wherein the second sub-transistor shared by the first pixel and the second pixel:
is connected in series with the first sub-transistor of the fifth transistor of the first pixel and is closer to the reference voltage line than the first sub-transistor of the fifth transistor of the first pixel; and
is connected in series with the first sub-transistor of the fifth transistor of the second pixel and is closer to the reference voltage line than the first sub-transistor of the fifth transistor of the second pixel, and
the first pixel and the second pixel share a contact area where the second sub-transistor is connected to the reference voltage line.

17. The display apparatus of claim 16, wherein the second sub-transistor is arranged at a boundary between the first pixel and the second pixel, and
wherein an arrangement of transistors of the first pixel, other than the second sub-transistor, and an arrangement of transistors of the second pixel, other than the second sub-transistor, are symmetric to each other with respect to the boundary between the first pixel and the second pixel.

18. The display apparatus of claim 11, wherein the fourth transistor comprises a first sub-transistor,
wherein the plurality of pixels further comprise a third pixel adjacent to the second pixel,
wherein the fourth transistor comprised in the second pixel and the fourth transistor comprised in the third pixel further comprise a second sub-transistor shared by the second pixel and the third pixel, and
wherein the second sub-transistor shared by the second pixel and the third pixel:
is connected in series with the first sub-transistor of the fourth transistor of the second pixel and is closer to the first initialization voltage line than the first sub-transistor of the fourth transistor of the second pixel; and
is connected in series with the first sub-transistor of the fourth transistor of the third pixel and is closer to the first initialization voltage line than the first sub-transistor of the fourth transistor of the third pixel.

19. The display apparatus of claim 18, wherein the second sub-transistor of the fourth transistor is arranged at a boundary between the second pixel and the third pixel, and
wherein an arrangement of transistors of the second pixel, other than the second sub-transistor, and an arrangement of transistors of the third pixel, other than the second sub-transistor, are symmetric to each other with respect to the boundary between the second pixel and the third pixel.

20. The display apparatus of claim 11, wherein each of the plurality of pixels further comprises:
a seventh transistor connected to a driving voltage line;
an eighth transistor connected to the second terminal of the first transistor and a light-emitting element; and
a ninth transistor connected to the light-emitting element and a second initialization voltage line,
wherein the plurality of pixels further comprise a third pixel adjacent to the second pixel, and
wherein the second pixel and the third pixel share a contact area where the ninth transistor of the second pixel and the ninth transistor of the third pixel are connected to the second initialization voltage line.
